(19) United States
(12) Patent Application Publication
(10) Pub. No.: US 2024/0379396 A1
(43) Pub. Date: Nov. 14, 2024

(54) SUBSTRATE PROCESSING APPARATUS

(71) Applicant: Brooks Automation US, LLC., Chelmsford, MA (US)

(72) Inventors: Levid E. Hanley, Lawrence, MA (US); Gregory E. Bejtlich, Portsmouth, NH (US)

(21) Appl. No.: 18/315,256

(22) Filed: May 10, 2023

(51) Int. Cl. H01L 21/677; H01L 21/687

(52) U.S. Cl. CPC H01L 21/67742; H01L 21/68707

(57) ABSTRACT

A substrate processing apparatus having a frame and at least one substrate transport arm connected to the frame. The at least one substrate transport arm having at least one end effector with a first and second substrate support tines, an end effector drive section configured to vary a distance between the first and second substrate support tines, and a slanted coupling that joins each of the first and second substrate support tines to each other substantially rigidly and unarticulated from one of the slanted coupling to another of the slanted coupling, the slanted coupling has a slanted axis of motion wherein each axis of motion of the slanted coupling is slanted with respect to each drive axis of the end effector drive section.

### BACKGROUND

### 1. Field

The exemplary embodiments generally relate to substrate processing apparatus, and more particularly, to handling of the substrates.

### 2. Brief Description of Related Developments

Integrated circuits are produced from wafers of semiconductor substrate material, such as silicon. Multiple integrated circuits are produced from each wafer. The typical fabrication facility is highly automated and uses substrate transport apparatus to transfer substrate wafers composed of partially fabricated integrated circuits between various fabrication tools.

To minimize defects in the integrated circuits, fabrication is carried out in clean rooms where specialized purification systems are employed to remove particle contaminates from the air and safeguards are used to prevent the creation of such contaminates. Dislocation of substrates during transport can cause particle contamination if the dislocated substrate strikes or rubs against another surface. In addition to damaging the dislocated substrate, other substrates can become contaminated with particles created due to the abrasion. Substrate transport apparatus with passive end effectors rely on friction between the end effector and the substrate to prevent dislocation, and therefore have lower operating speeds limited by the coefficient of static friction associated with the material of the passive pads (e.g. elastomeric material for low temperature conditions, or stainless steel, alumina, or quartz for high temperature conditions). Higher speeds are obtained by transport apparatus having active grip end effectors that apply a clamping force to the edge of a substrate as it is moved. Higher transport speeds are desired in the fabrication facility in order to increase production throughput.

Semiconductor substrate transport apparatus often operate within a chamber isolated to hold a controlled atmosphere, such as an inert gas or a vacuum. For example, a conventional substrate processing apparatus may comprise a vacuum chamber (or other chamber capable of holding an isolated atmosphere) with one or more processing modules capable of communicating with the chamber, and at least one load lock chamber to interface with the atmospheric environment outside. The apparatus further conventionally comprises a substrate transport apparatus with a movable arm for transporting substrates between the load lock chamber(s) and the processing modules, the arm being inside the vacuum chamber. It is desirable to use active edge grip end effectors on the transport apparatus for the above stated reasons. Active grip end effectors may employ a source of power and control to operate; however, a loss of power may cause release of the substrate held by the active grip end effectors where the active grippers of the end effector lose gripping force upon power loss. Conventional active edge grippers may also employ complicated linkages for actuating the active grip of the end effectors, where such linkages may cause varied actuation gripper velocities, varied gripping forces, and delayed or varied gripper actuation (such delay or variance in actuation being attributed to lost motion of the linkages as the linkages rotate). Moreover, multiple joints between the linkages may introduce play or slop in the gripper actuation.

It would be advantageous to have an active grip end effector that maintains an active grip on a substrate in the event of a power loss. It would also be advantageous to have an active grip end effector with a rigid and quick responding gripper actuator. It would further be advantageous to have an active grip end effector with a steady state velocity in gripper movement and a substantially constant gripping force throughout a complete range of motion of the grippers.

### BRIEF DESCRIPTION OF THE DRAWINGS

The foregoing aspects and other features of the disclosed embodiment are explained in the following description, taken in connection with the accompanying drawings, wherein:

FIGS. 1A-1H are schematic illustrations of a substrate processing apparatus incorporating aspects of the disclosed embodiment;

FIGS. 2A-2E are schematic illustrations of portions of substrate transport apparatus of FIGS. 1A-1H in accordance with aspects of the disclosed embodiment;

FIG. 3 is an exemplary schematic illustration of a substrate transport apparatus of FIGS. 1A-1H in accordance with aspects of the disclosed embodiment;

FIGS. 4A and 4B are schematic illustrations of a portion of the substrate transport apparatus of FIGS. 1A-3, respectively in a closed configuration and an open configuration, in accordance with aspects of the disclosed embodiment;

FIGS. 4C and 4D are schematic illustrations of the portion of the substrate transport apparatus of FIGS. 4A and 4B with a substrate thereon, respectively in a closed configuration and an open configuration, in accordance with aspects of the disclosed embodiment;

FIGS. 5A and 5B are schematic illustrations of a portion of the substrate transport apparatus of FIGS. 1A-3, respectively in a closed configuration and an open configuration, in accordance with aspects of the disclosed embodiment;

FIGS. 6A and 6B are schematic illustrations of a portion of the substrate transport apparatus of FIGS. 1A-3, in an open configuration, in accordance with aspects of the disclosed embodiment;

FIG. 7 is an exemplary flow diagram of a method in accordance with aspects of the disclosed embodiment; and

FIG. 8 is an exemplary flow diagram of a method in accordance with aspects of the disclose embodiment.

### DETAILED DESCRIPTION

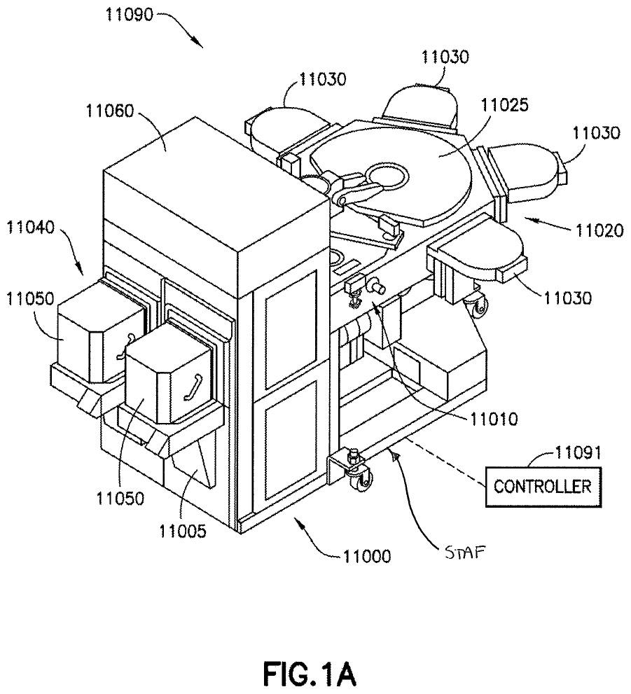

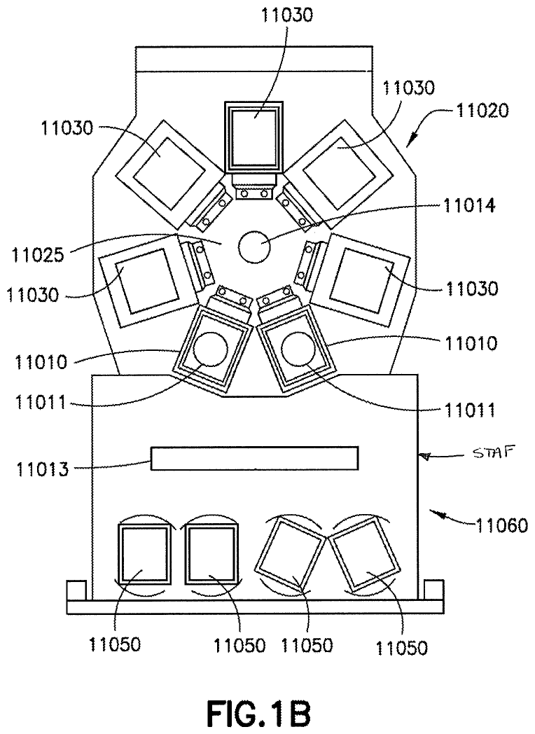

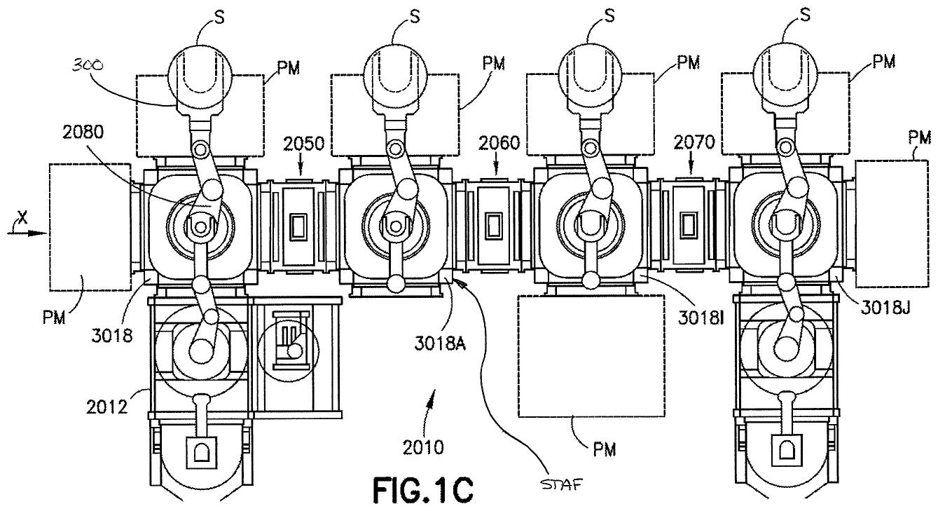

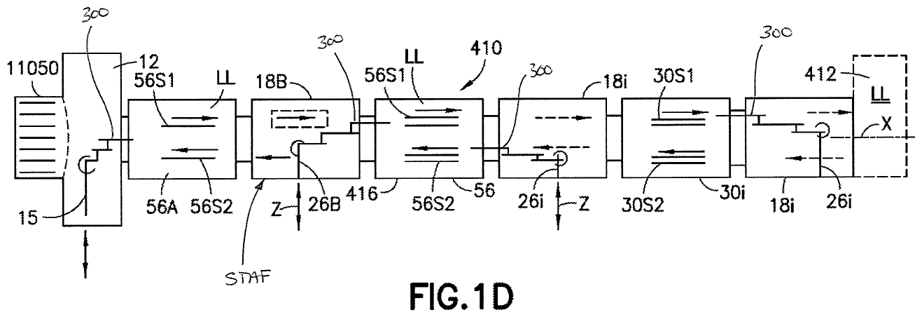

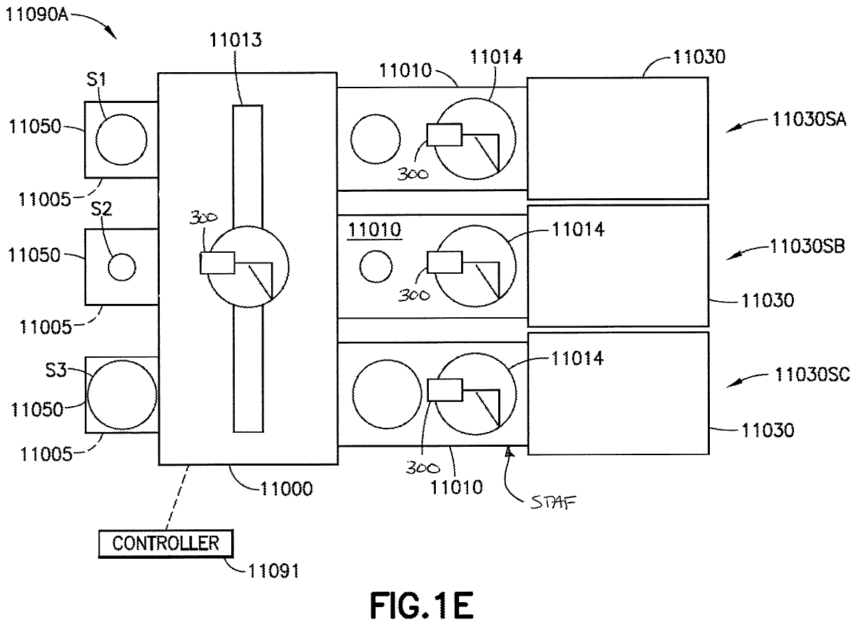

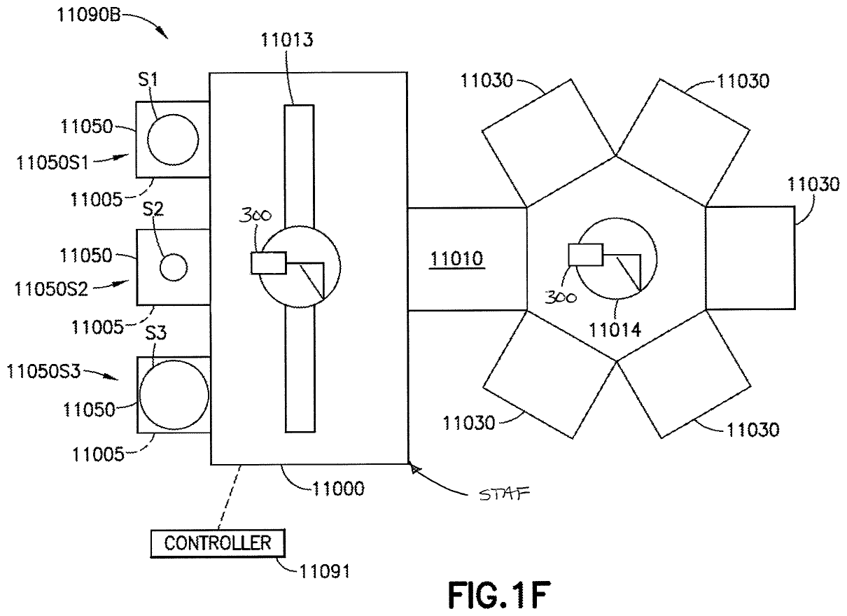

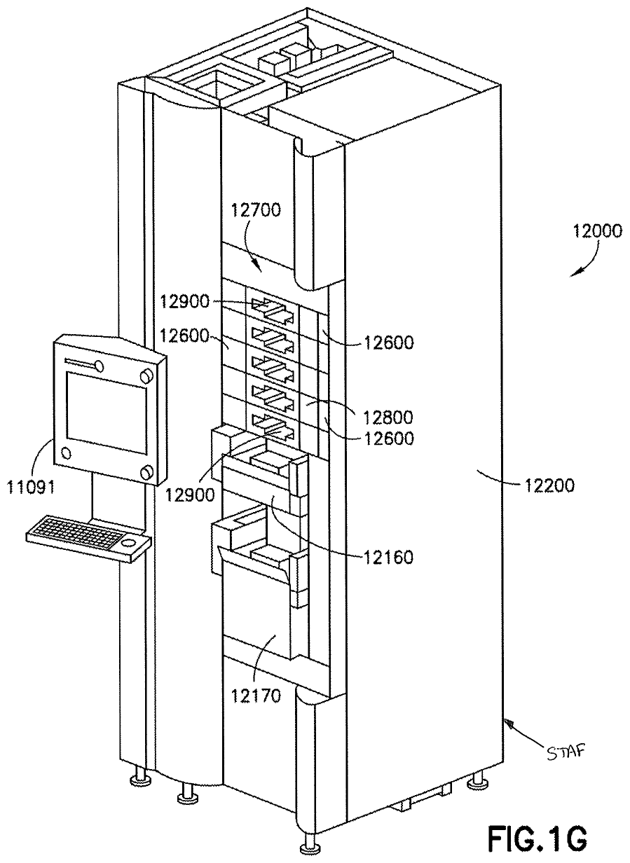

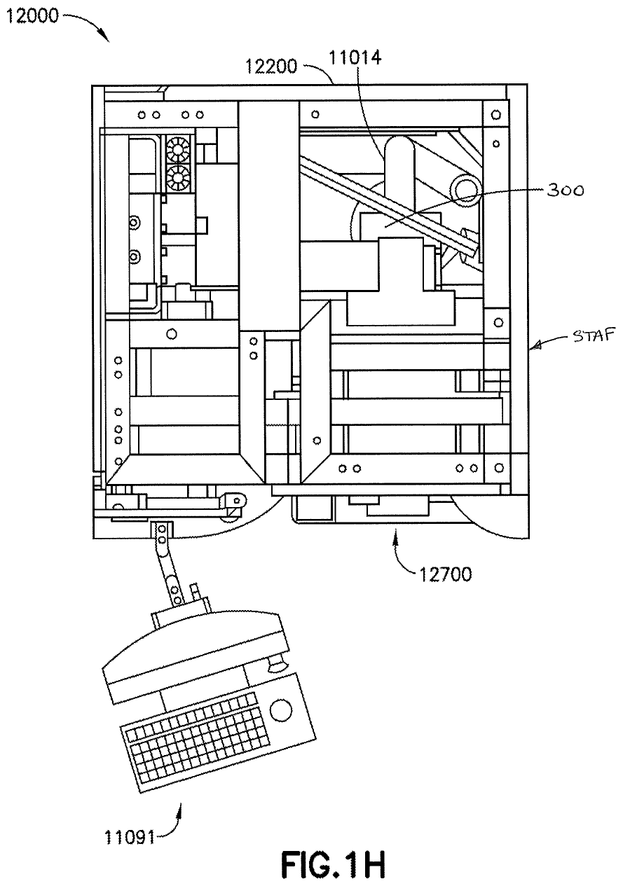

Referring to FIGS. 1A-1D, there are shown schematic views of substrate processing apparatus or tools incorporating the aspects of the disclosed embodiment as will be further described herein. Although the aspects of the disclosed embodiment will be described with reference to the drawings, it should be understood that the aspects of the disclosed embodiment can be embodied in many forms. In addition, any suitable size, shape or type of elements or materials could be used.

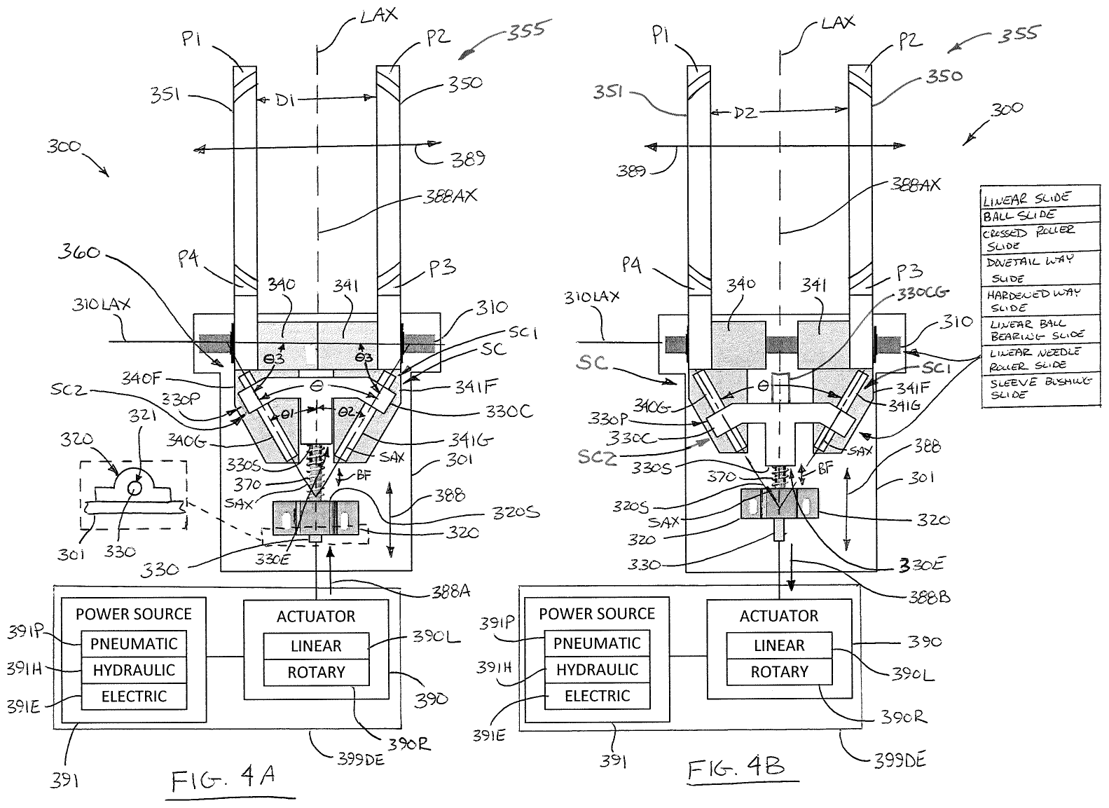

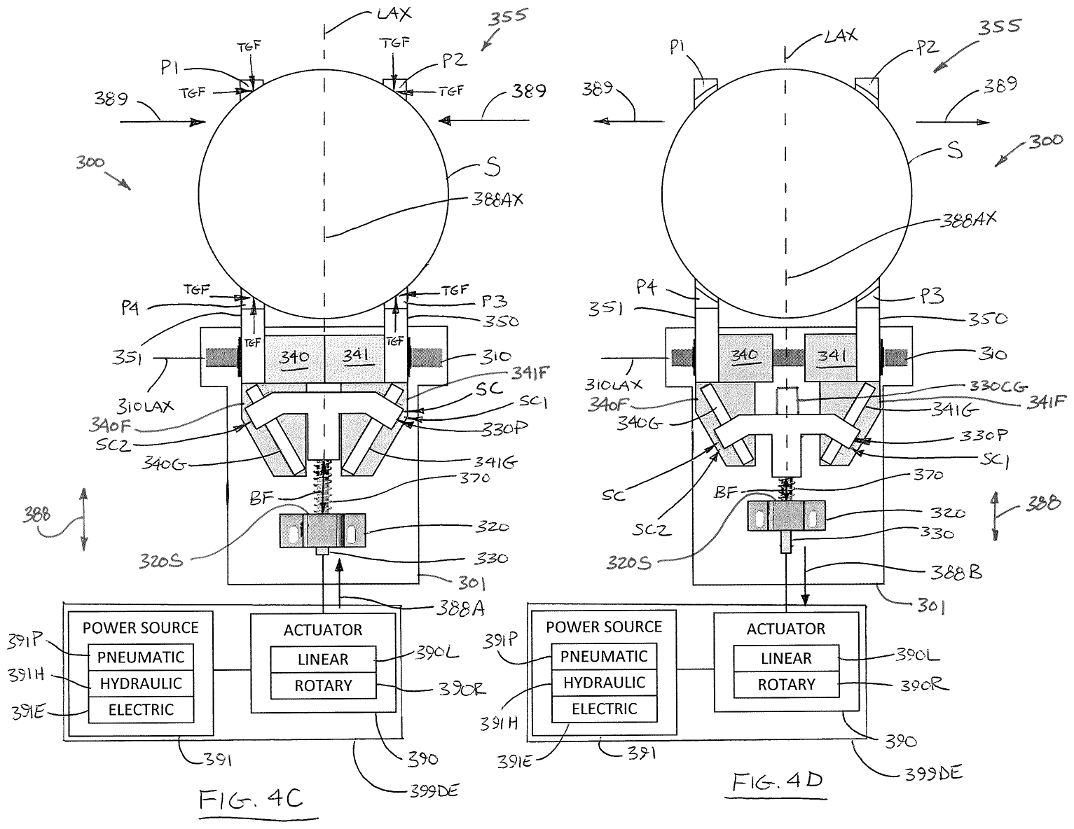

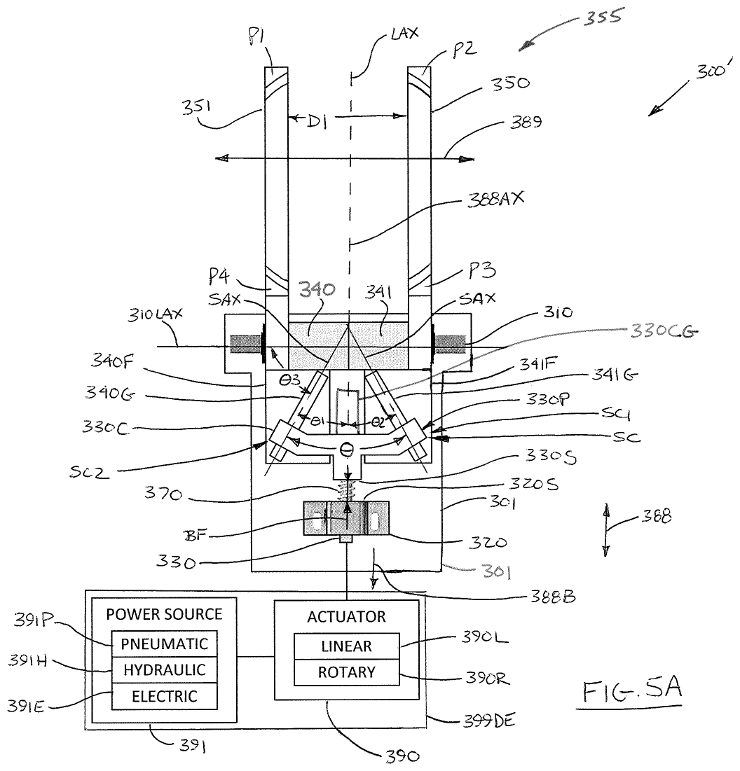

As will be described in greater detail below, the aspects of the disclosed embodiment provide an end effector for the handling of any suitable workpiece(s) (also referred to herein a substrate) such as, for example, semiconductor substrates, separated semiconductor devices/chips, reticles, reticle carriers or any other suitable trays (e.g. such as Joint Electron Device Engineering Council (JEDEC) or JEDEC style trays or any other tray that holds one or more items such as separated semiconductor devices/chips), carriers and/or tools semiconductor manufacturing, all of which are collectively referred to herein as “substrates”. The end effector includes an active grip that maintains a persistent substrate gripping force TGF (see FIG. 4C), for holding a substrate S on the end effector 300, 300′, 300″ (see FIGS. 4A-6), upon a loss of power to the end effector. The end effector also includes a slanted coupling SC (see FIGS. 4A-6) that couples a grip portion 355 of the end effector 300, 300′, 300″ to an end effector drive section 399DE, where the slanted coupling SC provides a substantially direct coupling of the end effector drive section 399DE to at least one substrate support tine 350, 351 of the grip portion 355 (see FIGS. 4A-6). This substantially direct coupling between the end effector drive section 399DE and the at least one substrate support tine 350, 351 effects a substantially constant/steady state velocity tine movement of the at least one substrate support tine 350, 351 and a constant/steady state gripping force for gripping a substrate S.

It is noted that the terms substrate and wafer are used interchangeably herein. Also, as used herein the term substrate holding station is a substrate holding location within a process module or any other suitable substrate holding location within the substrate processing apparatus such as, for example, a load port (or substrate cassette held thereon), a load lock, a buffer station, etc. on for picking/placing substrates to the substrate holding station.

Referring to FIGS. 1A and 1B, a processing apparatus, such as for example a semiconductor tool station or processing apparatus 11090 is shown in accordance with aspects of the disclosed embodiment. Although a semiconductor tool 11090 is shown in the drawings, the aspects of the disclosed embodiment described herein can be applied to any tool station or application employing robotic manipulators. In this example the tool 11090 is shown as a cluster tool, however the aspects of the disclosed embodiment may be applied to any suitable tool station such as, for example, a linear tool station such as that shown in FIGS. 1C and 1D and described in U.S. Pat. No. 8,398,355, entitled “Linearly Distributed Semiconductor Workpiece Processing Tool,” issued Mar. 19, 2013, the disclosure of which is incorporated by reference herein in its entirety. The tool station 11090 generally includes an atmospheric front end 11000, a vacuum load lock 11010 and a vacuum back end 11020. In other aspects, the tool station may have any suitable configuration. The components of each of the front end 11000, load lock 11010 and back end 11020 may be connected to a controller 11091, which may be part of any suitable control architecture such as, for example, a clustered architecture control. The control system may be a closed loop controller having a master controller, cluster controllers and autonomous remote controllers such as those disclosed in U.S. Pat. No. 7,904,182 entitled “Scalable Motion Control System” issued on Mar. 8, 2011 the disclosure of which is incorporated herein by reference in its entirety. In other aspects, any suitable controller and/or control system may be utilized. The controller 11091 includes any suitable memory and processor(s) that include non-transitory program code for operating the processing apparatus described herein to effect handling and mapping of substrates having varying sizes as described herein. For example, in one aspect, the controller 11091 includes embedded substrate locating commands. In one aspect, the substrate locating commands may be embedded pick/place commands for determining a distance between the substrate and end effector of the substrate transport apparatus as described herein. The controller is configured in any suitable manner to determine the location of the substrate(s) relative to the end effector and/or the substrate holding station to effect picking and placing of the substrate(s).

In one aspect, the front end 11000 generally includes load port modules 11005 and a mini-environment 11060 such as for example an equipment front end module (EFEM). The load port modules 11005 may be box opener/loader to tool standard (BOLTS) interfaces that conform to SEMI standards E15.1, E47.1, E62, E19.5 or E1.9 for 300 mm load ports, front opening or bottom opening boxes/pods and cassettes. In other aspects, the load port modules may be configured as 200 mm wafer or 450 mm wafer interfaces or any other suitable substrate interfaces such as for example larger or smaller wafers or flat panels for flat panel displays. Although two load port modules 11005 are shown in FIG. 1A, in other aspects any suitable number of load port modules may be incorporated into the front end 11000. The load port modules 11005 may be configured to receive substrate carriers or cassettes 11050 from an overhead transport system, automatic guided vehicles, person guided vehicles, rail guided vehicles or from any other suitable transport method. The load port modules 11005 may interface with the mini-environment 11060 through load ports 11040. In one aspect, the load ports 11040 allow the passage of substrates between the substrate cassettes 11050 and the mini-environment 11060.

In one aspect, the mini-environment 11060 generally includes any suitable transfer robot 11013 that incorporates one or more aspects of the disclosed embodiment described herein. In one aspect the robot 11013 may be a track mounted robot such as that described in, for example, U.S. Pat. No. 6,002,840, the disclosure of which is incorporated by reference herein in its entirety or in other aspects, any other suitable transport robot having any suitable configuration. The mini-environment 11060 may provide a controlled, clean zone for substrate transfer between multiple load port modules.

The vacuum load lock 11010 may be located between and connected to the mini-environment 11060 and the back end 11020. It is noted that the term vacuum as used herein may denote a high vacuum such as 1×10⁻⁵ Torr (0.0013 Pa) or below in which the substrates are processed. The load lock 11010 generally includes atmospheric and vacuum slot valves. The slot valves may provide the environmental isolation employed to evacuate the load lock after loading a substrate from the atmospheric front end and to maintain the vacuum in the transport chamber when venting the lock with an inert gas such as nitrogen. In one aspect, the load lock 11010 includes an aligner 11011 for aligning a fiducial of the substrate to a desired position for processing. In other aspects, the vacuum load lock may be located in any suitable location of the processing apparatus and have any suitable configuration and/or metrology equipment.

The vacuum back end 11020 generally includes a transport chamber 11025, one or more processing station(s) or module(s) 11030 and any suitable transfer robot or apparatus 11014. The transfer robot 11014 will be described below and may be located within the transport chamber 11025 to transport substrates between the load lock 11010 and the various processing stations 11030. The processing stations 11030 may operate on the substrates through various deposition, etching, or other types of processes to form electrical circuitry or other desired structure on the substrates. Typical processes include but are not limited to thin film processes that use a vacuum such as plasma etch or other etching processes, chemical vapor deposition (CVD), plasma vapor deposition (PVD), implantation such as ion implantation, metrology, rapid thermal processing (RTP), dry strip atomic layer deposition (ALD), oxidation/diffusion, forming of nitrides, vacuum lithography, epitaxy (EPI), wire bonder and evaporation or other thin film processes that use vacuum pressures. The processing stations 11030 are connected to the transport chamber 11025 to allow substrates to be passed from the transport chamber 11025 to the processing stations 11030 and vice versa. In one aspect the load port modules 11005 and load ports 11040 are substantially directly coupled to the vacuum back end 11020 so that a cassette 11050 mounted on the load port interfaces substantially directly (e.g. in one aspect at least the mini-environment 11060 is omitted while in other aspects the vacuum load lock 11010 is also omitted such that the cassette 11050 is pumped down to vacuum in a manner similar to that of the vacuum load lock 11010) with a vacuum environment of the transfer chamber 11025 and/or a processing vacuum of a processing station 11030 (e.g. the processing vacuum and/or vacuum environment extends between and is common between the processing station 11030 and the cassette 11050).

Referring now to FIG. 1C, a schematic plan view of a linear substrate processing system 2010 is shown where the tool interface section 2012 is mounted to a transport chamber module 3018 so that the interface section 2012 is facing generally towards (e.g. inwards) but is offset from the longitudinal axis X of the transport chamber 3018. The transport chamber module 3018 may be extended in any suitable direction by attaching other transport chamber modules 3018A, 3018I, 3018J to interfaces 2050, 2060, 2070 as described in U.S. Pat. No. 8,398,355, previously incorporated herein by reference. Each transport chamber module 3018, 3019A, 3018J 3018I, includes any suitable substrate transport 2080, which may include one or more aspects of the disclosed embodiment described herein, for transporting substrates throughout the processing system 2010 and into and out of, for example, processing modules PM (which in one aspect are substantially similar to processing stations 11030 described above). As may be realized, each chamber module may be capable of holding an isolated or controlled atmosphere (e.g. N2, clean air, vacuum).

Referring to FIG. 1D, there is shown a schematic elevation view of an exemplary processing tool 410 such as may be taken along longitudinal axis X of the linear transport chamber 416. In the aspect of the disclosed embodiment shown in FIG. 1D, tool interface section 12 may be representatively connected to the transport chamber 416. In this aspect, interface section 12 may define one end of the tool transport chamber 416. As seen in FIG. 1D, the transport chamber 416 may have another workpiece entry/exit station 412 for example at an opposite end from interface station 12. In other aspects, other entry/exit stations for inserting/removing workpieces from the transport chamber may be provided. In one aspect, interface section 12 and entry/exit station 412 may allow loading and unloading of workpieces from the tool. In other aspects, workpieces may be loaded into the tool from one end and removed from the other end. In one aspect, the transport chamber 416 may have one or more transfer chamber module(s) 18B, 18i. Each chamber module may be capable of holding an isolated or controlled atmosphere (e.g. N2, clean air, vacuum). As noted before, the configuration/arrangement of the transport chamber modules 18B, 18i, load lock modules 56A, 56 and workpiece stations forming the transport chamber 416 shown in FIG. 1D is merely exemplary, and in other aspects the transport chamber may have more or fewer modules disposed in any desired modular arrangement. In the aspect shown, station 412 may be a load lock. In other aspects, a load lock module may be located between the end entry/exit station (similar to station 412) or the adjoining transport chamber module (similar to module 18i) may be configured to operate as a load lock.

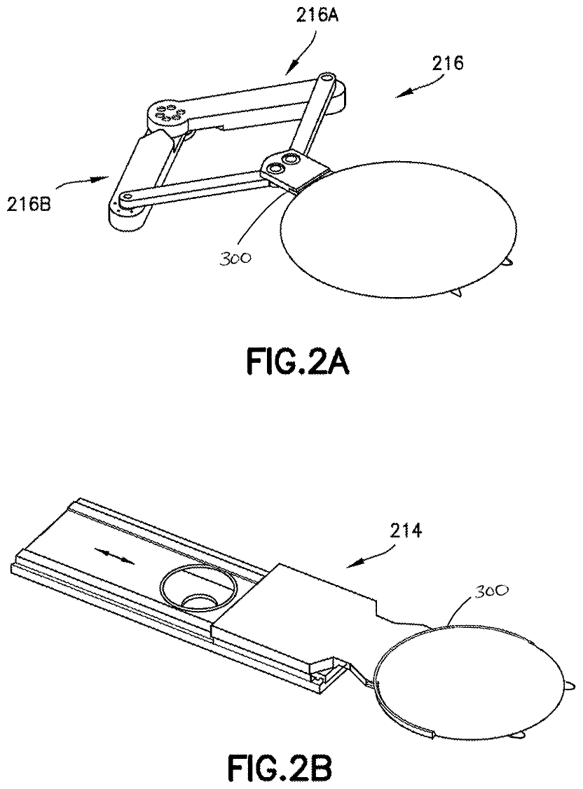

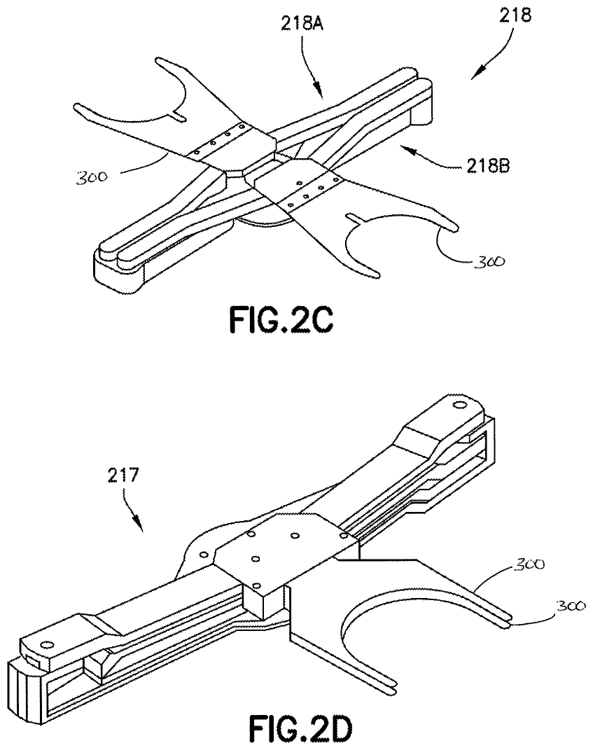

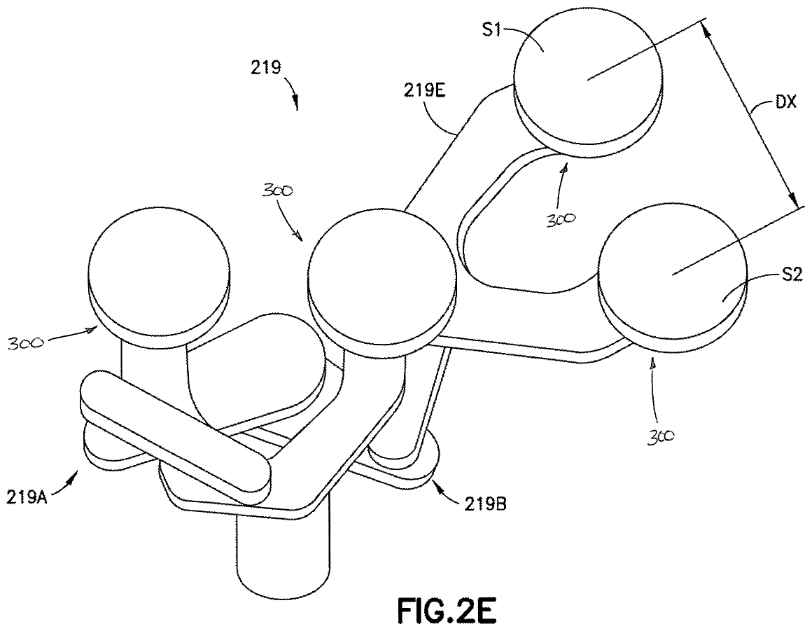

As also noted before, transport chamber modules 18B, 18i have one or more corresponding transport apparatus 26B, 26i located therein, which transport apparatus may include one or more aspects of the disclosed embodiment described herein. The transport apparatus 26B, 26i of the respective transport chamber modules 18B, 18i may cooperate to provide the linearly distributed workpiece transport system in the transport chamber. In this aspect, the transport apparatus 26B (which may be substantially similar to the transport apparatus 11013, 11014 of the cluster tool illustrated in FIGS. 1A and 1B) may have a general SCARA arm configuration (though in other aspects the transport arms may have any other desired arrangement such as, for example, a linearly sliding arm 214 as shown in FIG. 2B or other suitable arms having any suitable arm linkage mechanisms. Suitable examples of arm linkage mechanisms can be found in, for example, U.S. Pat. No. 7,578,649 issued Aug. 25, 2009, U.S. Pat. No. 5,794,487 issued Aug. 18, 1998, U.S. Pat. No. 7,946,800 issued May 24, 2011, U.S. Pat. No. 6,485,250 issued Nov. 26, 2002, U.S. Pat. No. 7,891,935 issued Feb. 22, 2011, U.S. Pat. No. 8,419,341 issued Apr. 16, 2013 and U.S. patent application Ser. No. 13/293,717 entitled “Dual Arm Robot” and filed on Nov. 10, 2011 and Ser. No. 13/861,693 entitled “Linear Vacuum Robot with Z Motion and Articulated Arm” and filed on Sep. 5, 2013 the disclosures of which are all incorporated by reference herein in their entireties. In aspects of the disclosed embodiment, the at least one transfer arm may be derived from a conventional SCARA (selective compliant articulated robot arm) type design, which includes an upper arm, a band-driven forearm and a band-constrained end-effector, or from a telescoping arm or any other suitable arm design. Suitable examples of transfer arms can be found in, for example, U.S. patent application Ser. No. 12/117,415 entitled “Substrate Transport Apparatus with Multiple Movable Arms Utilizing a Mechanical Switch Mechanism” filed on May 8, 2008 and U.S. Pat. No. 7,648,327 issued on Jan. 19, 2010, the disclosures of which are incorporated by reference herein in their entireties. The operation of the transfer arms may be independent from each other (e.g. the extension/retraction of each arm is independent from other arms), may be operated through a lost motion switch or may be operably linked in any suitable way such that the arms share at least one common drive axis. In still other aspects the transport arms may have any other desired arrangement such as a frog-leg arm 216 (FIG. 2A) configuration, a leap frog arm 217 (FIG. 2D) configuration, a bi-symmetric arm 218 (FIG. 2C) configuration, etc. In another aspect, referring to FIG. 2E, the transfer arm 219 includes at least a first and second articulated arm 219A, 219B where each arm 219A, 219B includes an end effector 219E configured to hold at least two substrates S1, S2 side by side in a common transfer plane (each substrate holding location of the end effector 219E shares a common drive for picking and placing the substrates S1, S2) where the spacing DX between the substrates S1, S2 corresponds to a fixed spacing between side by side substrate holding locations. Suitable examples of transport arms can be found in U.S. Pat. No. 6,231,297 issued May 15, 2001, U.S. Pat. No. 5,180,276 issued Jan. 19, 1993, U.S. Pat. No. 6,464,448 issued Oct. 15, 2002, U.S. Pat. No. 6,224,319 issued May 1, 2001, U.S. Pat. No. 5,447,409 issued Sep. 5, 1995, U.S. Pat. No. 7,578,649 issued Aug. 25, 2009, U.S. Pat. No. 5,794,487 issued Aug. 18, 1998, U.S. Pat. No. 7,946,800 issued May 24, 2011, U.S. Pat. No. 6,485,250 issued Nov. 26, 2002, U.S. Pat. No. 7,891,935 issued Feb. 22, 2011 and U.S. patent application Ser. No. 13/293,717 entitled “Dual Arm Robot” and filed on Nov. 10, 2011 and U.S. patent application Ser. No. 13/270,844 entitled “Coaxial Drive Vacuum Robot” and filed on Oct. 11, 2011 the disclosures of which are all incorporated by reference herein in their entireties. The aspects of the disclosed embodiment are, in one aspect, incorporated into the transport arm of a linear transport shuttle such as those described in, for example, U.S. Pat. Nos. 8,293,066 and 7,988,398 the disclosures of which are incorporated herein by reference in their entireties.

In the aspect of the disclosed embodiment shown in FIG. 1D, the arms of the transport apparatus 26B may be arranged to provide what may be referred to as fast swap arrangement allowing the transport to quickly swap wafers (e.g. pick a wafer from a substrate holding location and then immediately place a wafer to the same substrate holding location) from a pick/place location. The transport arm 26B may have any suitable drive section (e.g. coaxially arranged drive shafts, side by side drive shafts, horizontally adjacent motors, vertically stacked motors, etc.), for providing each arm with any suitable number of degrees of freedom (e.g. independent rotation about shoulder and elbow joints with Z axis motion). As seen in FIG. 1D, in this aspect the modules 56A, 56, 30i may be located interstitially between transfer chamber modules 18B, 18i and may define suitable processing modules, load lock(s) LL, buffer station(s), metrology station(s) or any other desired station(s). For example, the interstitial modules, such as load locks 56A, 56 and workpiece station 30i, may each have stationary workpiece supports/shelves 56S1, 56S2, 30S1, 30S2 that may cooperate with the transport arms to effect transport or workpieces through the length of the transport chamber along linear axis X of the transport chamber. By way of example, workpiece(s) may be loaded into the transport chamber 416 by interface section 12. The workpiece(s) may be positioned on the support(s) of load lock module 56A with the transport arm 15 of the interface section. The workpiece(s), in load lock module 56A, may be moved between load lock module 56A and load lock module 56 by the transport arm 26B in module 18B, and in a similar and consecutive manner between load lock 56 and workpiece station 30i with arm 26i (in module 18i) and between station 30i and station 412 with arm 26i in module 18i. This process may be reversed in whole or in part to move the workpiece(s) in the opposite direction. Thus, in one aspect, workpieces may be moved in any direction along axis X and to any position along the transport chamber and may be loaded to and unloaded from any desired module (processing or otherwise) communicating with the transport chamber. In other aspects, interstitial transport chamber modules with static workpiece supports or shelves may not be provided between transport chamber modules 18B, 18i. In such aspects, transport arms of adjoining transport chamber modules may pass off workpieces directly from end effector or one transport arm to end effector of another transport arm to move the workpiece through the transport chamber. The processing station modules may operate on the substrates through various deposition, etching, or other types of processes to form electrical circuitry or other desired structure on the substrates. The processing station modules are connected to the transport chamber modules to allow substrates to be passed from the transport chamber to the processing stations and vice versa. A suitable example of a processing tool with similar general features to the processing apparatus depicted in FIG. 1D is described in U.S. Pat. No. 8,398,355, previously incorporated by reference in its entirety.

FIG. 1E is a schematic illustration of a semiconductor tool station 11090A which may be substantially similar to the semiconductor tool stations described above. Here, the semiconductor tool station 11090A includes separate/distinct in-line processing sections 11030SA, 11030SB, 11030SC connected to a common atmospheric front end 11000. In this aspect, at least one of the in-line processing sections 11030SA, 11030SB, 11030SC is configured to process a substrate S1, S2, S3 that has a different predetermined characteristic than the substrates processed in the other in-line processing sections 11030SA, 11030SB, 11030SC. For example, the predetermined characteristic may be a size of the substrate. In one aspect, for exemplary purposes only, in-line processing section 11030SA may be configured to process 200 mm diameter substrates, in-line processing section 11030SB may be configured to process 150 mm substrates, and in-line processing section 11030SC may be configured to process 300 mm substrates.

FIG. 1F is a schematic illustration of a semiconductor tool station 11090B substantially similar to semiconductor tool station 11090. However, in this aspect, the process modules 11030 and load port modules 11005 are configured to process substrates having different sizes as above with respect to semiconductor tool station 11090A. In this aspect, the process modules 11030 may be configured to process substrates having different sizes or in other aspects, process modules may be provided that correspond to the different size substrates being processed in the semiconductor tool station 11090B.

Referring to FIGS. 1G and 1H, the aspects of the disclosed embodiment may be incorporated into sorting machines and/or stockers. In one aspect, the sorting machines and/or stockers may be used to sort or stock substrates (such as those described above). As an example, FIGS. 1G and 1H illustrate a manipulating device 12000 substantially similar to that described in U.S. Pat. No. 7,699,573 issued on Apr. 20, 2010, the disclosure of which is incorporated herein by reference in its entirety. Here the manipulating device 12000 may be configured to manipulate substrates such as reticles but in other aspects the manipulating device 12000 may be configured to manipulate any suitable substrate. The manipulating device 12000 may be a modular device having a housing 12200 for maintaining clean a room environment within the housing 12200. The manipulating device 12000 includes an input/output station 12700 integrated into the housing 12200 that includes panels 12600. Each panel 12600 belongs to an input/output unit 12800, which is also modular. One edge of an opening 12900 of the respective panel 12600 is provided with a contour that corresponds at least approximately to the outer contour of each type of substrate (such as e.g. a reticle transport box) that is to be processed by the manipulating device 12000. The openings 12900 are configured so that the substrates can be input/output through the openings 12900 to and from the manipulating device 12000. In one aspect, the manipulating device 12000 also includes drawers 12170, 12160 that are components of additional input/output units 12800 of station 12700. The drawers 12170, 12160 may have different structural height and can be pulled out to accept larger transport boxes, for example, those which can accommodate more than one substrate, i.e. the larger transport boxes can be introduced into the manipulating device 12000 through the drawers 12160, 12170. The manipulating device 12000 also includes at least one transport apparatus 11014 substantially similar to those described herein. The at least one transport apparatus is configured to transport the one or more substrates within the manipulating device 12000 for sorting, stocking or for any other processing operation(s). It is noted that the configuration of the manipulating device 12000 described herein is exemplary and in other aspects, the manipulating device may have any suitable configuration for sorting and/or stocking substrates in any suitable manner.

In one aspect, the manipulating device 12000 may be included in the semiconductor tool stations of FIGS. 1A-1F described above. For example, in one aspect, the manipulating device 12000 may be incorporated in the atmospheric front end 11000 of the semiconductor tool stations/systems 11090, 2010, 11090A, 11090B as a load port and/or atmospheric transfer chamber; while in other aspects the manipulating device may be incorporated in the vacuum back end 11020 of the semiconductor tool stations/systems 11090, 2010, 11090A, 11090B as a process module and/or a transfer chamber. In one aspect, the manipulating device 12000 may be coupled to the atmospheric front end 11000 in place of the vacuum back end 11020.

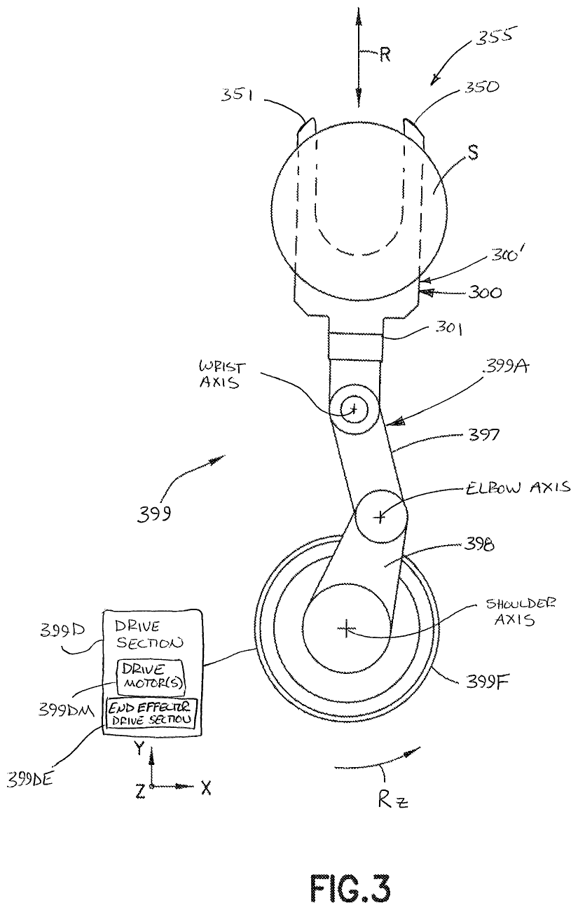

Referring to FIG. 3, an exemplary substrate transport apparatus 399 is illustrated. The substrate transport 399 is illustrated as having a SCARA arm configuration; however, in other aspects the substrate transport apparatus 399 may have any suitable configuration including, but not limited to, those described herein with respect to FIGS. 1A-2E. The substrate transport apparatus 399 includes a frame 399F (which may be coupled to a frame STAF of a substrate processing apparatus such as those described above) and at least one substrate transport arm 399A coupled to the frame 399F, where the at least one substrate transport arm 399A has at least one end effector 300, 300′, 300″. Each of the at least one substrate transport arm 399A includes an upper arm 398, a forearm 397, and at least one of the at least one end effector 300, 300′; however, in other aspects each substrate transport arm 399A includes any suitable number of articulated arm links. The substrate transport apparatus 399 includes any suitable drive section 399D having any suitable number of drive motors 399DM for moving the transport arm 399A in any suitable numbers of degrees of freedom including, but not limited to, rotation Rz about a shoulder axis, linearly along the Z axis, and extension in the R direction in an X-Y plane. The drive section 399D includes an end effector drive section 399DE, as will be described further herein, for effecting gripping and releasing substrate(s) with the at least one end effector 300, 300′, 300″.

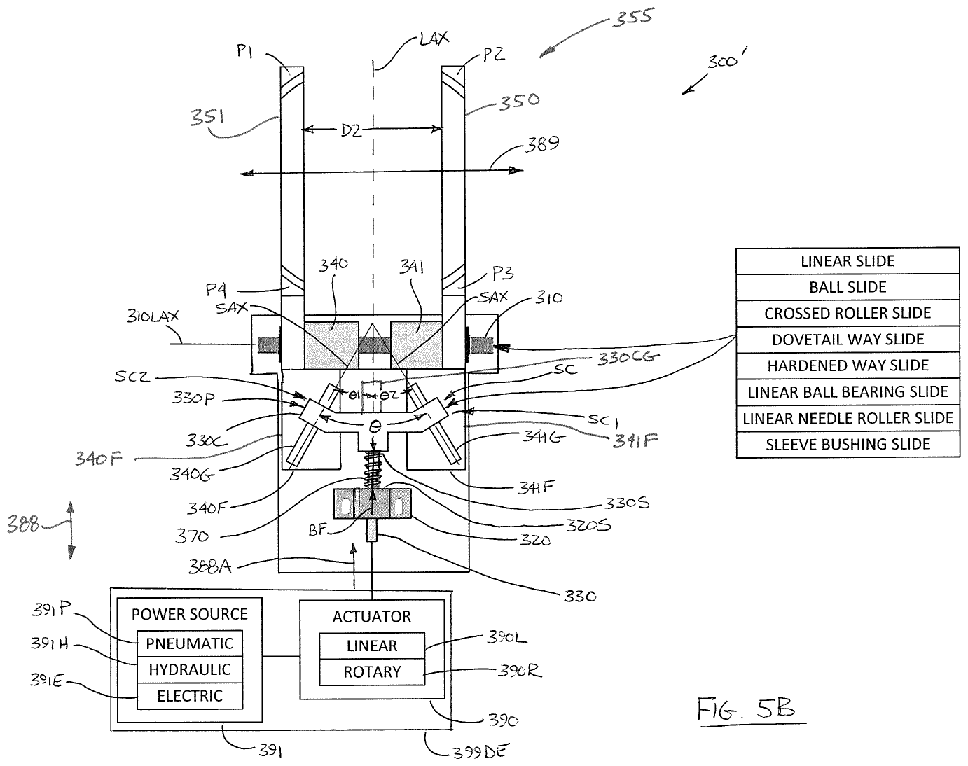

Referring also to FIGS. 4A, 4B, 4C, 4D, 5A, 5B, and 6 the at least one end effector 300, 300′, 300″ may be referred to as an active grip or edge grip end effector having substrate support tines 350, 351. Each of the first and second substrate support tines 350, 351 have respective substrate contacts P1-P4 configured to contact and support a substrate S held by the end effector 300, 300′, 300″ between the respective substrate contacts P1-P4 of the first and second substrate support tines 350,351 (as described herein). As described herein, the first and second support tines 350, 351 are moved along an output axis (e.g., such as along axis 310LAX) from a release position (see FIGS. 4B, 4D, 5B, and 6) releasing a substrate S and a support position (see FIGS. 4A, 4C, and 5A) in which the first and second support tines 350, 351 are disposed to contact and support the substrate S. The tines 350, 351 are moved by any suitable powered actuator so that the substrate contacts P1-P4 engage (so as to support) and grip the edge(s) of the substrate S. Suitable examples of edge grip substrate contacts can be found in, for example, U.S. Pat. No. 9,437,469 (titled “Inertial Wafer Centering End Effector and Transport Apparatus,” issued on Sep. 6, 2016) and U.S. Pat. No. 10,204,811 (titled “Substrate Transport Apparatus with Active Edge Gripper,” issued on Feb. 12, 2019), the disclosures of which are incorporated herein by reference in their entireties. The at least one end effector 300 of the substrate transport apparatus 399 is configured, as described herein, so as to maintain a persistent and substantially constant/steady state grip (e.g., gripping force TGF—see FIG. 4C) that is applied a substrate S in the event of a loss of power to the end effector 300, 300′, 300″ (such as a loss of power to the tine actuator).

Each of the at least one end effector 300, 300′, 300″ includes a frame or base portion 301, a grip portion 355 with a first and second substrate support tines 350, 351, at least a portion of the end effector drive section 399DE, and the slanted coupling SC. The base portion 301 is configured for coupling with a respective substrate transport arm 399A. For example, the base portion 301 is coupled to the respective substrate transport arm 399A at a wrist joint or axis in any suitable manner, such as illustrated and described with respect to FIGS. 1C-1F, 1H, 2A-2E, and 3. The base portion 301 has a longitudinal axis LAX. Coupled to the base portion 301, so as to have a fixed steady state relationship with the base portion 301, are at least one tine guide bearing 310 and a guide block 320.

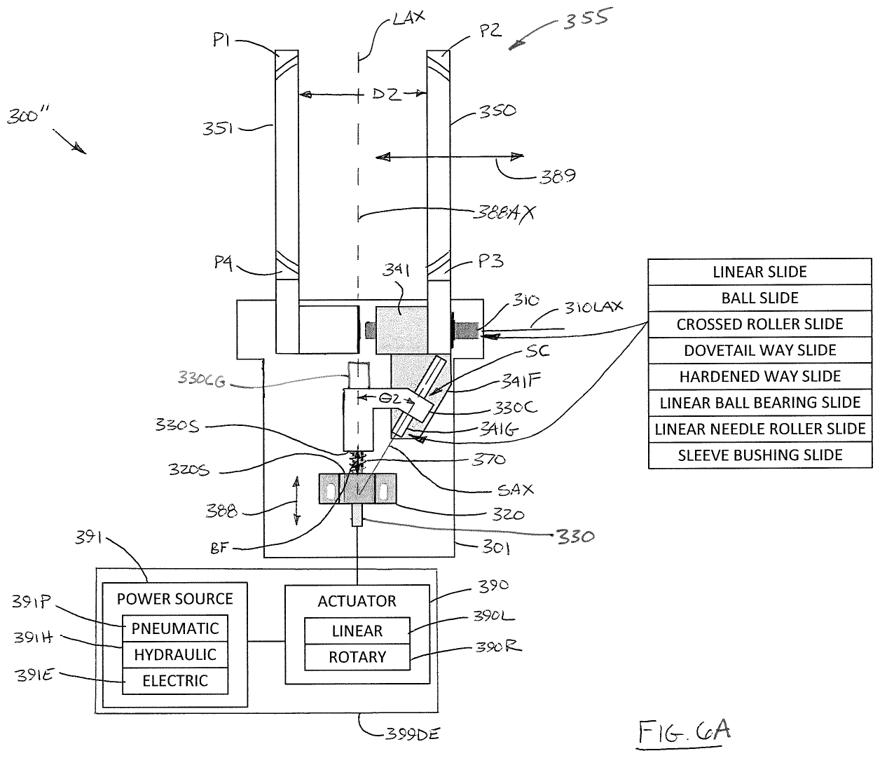

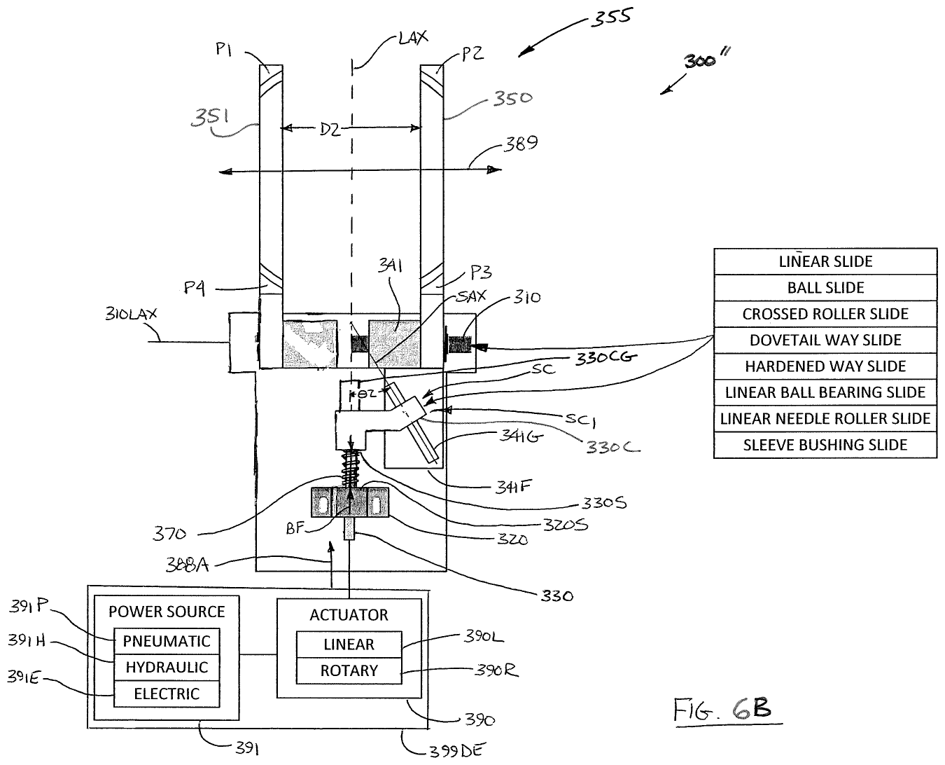

The first and second substrate support tines 350, 351 are mounted to and are dependent (e.g., supported) from the base portion 301 where at least one of the first and second substrate support tines 350, 351 is movable relative to the base portion 301. As an example, one or more of the first and second substrate support tines 350, 351 are configured to traverse the at least one tine guide bearing 310 and interface with and support a substrate S (see FIGS. 4C and 4D) on the end effector 300, 300′, 300″ for transport of the substrate S. While both of the first substrate support tine 350 and the second substrate support tine 351 are illustrated in FIGS. 4A-5B as being movable relative to the base portion 301, in other aspects one of the first and second substrate support tines 350, 351 may be fixed or stationary relative to the base portion 301 while the other of the first and second substrate support tines is movable relative to the base portion 301 (e.g., see FIGS. 6A and 6B where end effector 300″ includes fixed tine 351 and movable tine 350 with the tines 350, 351 shown in an open position).

The at least one tine guide bearing 310 may be any suitable linear sliding coupling or bearing that is coupled to the base portion 301 in any suitable manner (e.g., mechanical or chemical fasteners, etc.) and in an orientation so that a lengthwise axis 310LAX of the tine guide bearing 310 extends substantially orthogonal to the longitudinal axis LAX of the base portion 301. The lengthwise axis 310LAX forms an output axis of the end effector drive section 399DE. While one tine guide bearing 310 is illustrated in the figures, there may be more than one tine guide bearing 310 arranged in parallel with respect to other tine guide bearings 310 to guide movement of one or more of the first and second tines 350, 351 in direction 389, transverse to the longitudinal axis LAX in the manner described herein.

The guide block 320 is coupled to the base portion 301 in any suitable manner (e.g., mechanical or chemical fasteners, etc.) and includes a guide aperture 321 through which a drive shaft 330 of the end effector 300 extends. The guide block 320 is coupled to the base portion 301 so that the guide aperture 321 extends substantially along (or substantially parallel with) the longitudinal axis LAX of the base portion 301. Here, the drive shaft 330 also extends substantially along (or substantially parallel with) the longitudinal axis LAX via the drive shaft 330 interface with the guide aperture and reciprocates in direction 388 within the guide aperture 321 (e.g., the drive shaft 330 passes through and is guided in movement by the guide aperture) to open and close the tines 350, 351 in the manner described herein. The drive shaft 330 is coupled to and is driven by the end effector drive section 399D. The end effector drive section 399D is configured to vary a distance between the first and second substrate support tines 350, 351.

The end effector drive section 399D may have any suitable actuator or drive 390 that generates a linear drive input (e.g., in direction 388) along a drive axis 388AX, and the actuator 390 is coupled to the grip portion 355 by the slanted coupling SC that operably joins each of the first and second substrate support tines 350, 351 to the actuator 390. For example, the actuator 390 may include, but is not limited to, one or more of a linear actuator 390L and a rotary actuator 390R. The actuator 390 may be coupled to the base portion 301 of the end effector 300 in any suitable manner so as to couple with (e.g., via a direct connection or through any suitable transmission) and drive the drive shaft 330 in the manner described herein. The actuator 390 is powered by any suitable power source 391. In one aspect, the power source 391 is a fluidic power source including, but not limited to, one or more of a pneumatic power source 391P and a hydraulic power source 391H. In other aspects, the power source 391 is an electric power source 391E. The power source may be at least partially disposed on the base portion 301 of the end effector, in the drive section 399D of the robot, or at any other suitable location onboard or off-board the substrate transport apparatus 399.

The end effector 300 incudes at least one carriages 340, 341 (e.g., a carriage for each movable substrate support tine) that travel(s) along and is/are guided by the at least one tine guide bearing 310. Each carriage 340, 341 includes a frame 340F, 341F that forms with the at least one tine guide bearing 310 a linear slide, a ball slide, a crossed roller slide, a dovetail way slide, a hardened way slide, a linear ball bearing slide, a linear needle roller slide, a sleeve bushing slide, or any other suitable slide. A respective substrate support tine 350, 351 is coupled to and supported by a respective frame 340F, 341F so that the respective substrate support tine 350, 351 is cantilevered from the carriage 340, 341. The tines 350, 351 are coupled to frame 340F, 341F of the respective carriage 340, 341 in any suitable manner including, but not limited to, any suitable mechanical, magnetic, or chemical fasteners.

As described herein, the coupling 360 is configured so as to translate the linear drive input (e.g., in direction 388A), of the actuator 390, to an output (e.g., along axis 310LAX) imparted to and moving at least one or each of the first and second substrate support tines 350, 351 in a direction (e.g., direction 389) substantially orthogonal to the linear drive input along the drive axis 388AX. The coupling 360 has a tie member 330C, rigid and unarticulated, that connects the first and second substrate support tines 350, 351 to each other and to the actuator 390 (as described herein), so that the drive input is common to the output imparted to and moving each of the first and second substrate support tines 350, 351. The coupling 360, via the tie member 330C, provides a substantially direct and rigid coupling between the actuator 390 and at least one of the first and second support tines 350, 351 so that the at least one of the substrate support tines 350, 351 moves substantially immediately with movement of the actuator 390 (e.g., without lagging movement relative to actuator 390 movement). The direct rigid coupling between the actuator 390 and the substrate support tines 350, 351 (effected by the coupling 360) provides for increased control of substrate support tine 350, 351 movement compared to conventional active grip end effectors having, for example, rotating links driving movement of the substrate support tines.

The end effector 300, 300′, 300″ includes the slanted coupling SC formed at least in part by the tie member 330C, that has a slanted axis of motion SAX. Each axis of motion SAX of the slanted coupling SC is slanted with respect to each drive axis 388AX (e.g., the drive axis defined by direction 388) of the end effector drive section 399DE. The tie member 330C has an end 330E joined to the actuator 390 so that the drive input (from the actuator 390) impinges against the tie member 330C, and the tie member 330C spans between and is movably connected (as described herein) to the first and second substrate support tines 350, 351. The tie member 330C is constrained to move linearly along the drive axis 388AX by any suitable linear guide 330CG (see FIGS. 4B, 4D, and 5A-6B, noting the linear guide 330CG is not shown in FIGS. 4A and 4C for clarity). The constrained linear movement of the tie member 330C along the linear guide 330CG effects substantially equal and opposite movement of the support tines 350, 351 through interaction of the tie member 330C with at least one pitched linear guides 340G, 341G, pitched at a pitch angle θ1, θ2, with respect to the drive axis 388AX and with respect to each other. The interface between the tie member 330C and the at least one pitched linear guides 340G, 341G provides for a constant velocity movement of the at least one substrate support tine 350, 351 and application of a constant substrate gripping force TGF.

As described herein, the slanted coupling SC includes a first and second slanted couplings (referred to herein as first and second slanted coupling portions SC1, SC2), each slanted coupling portion SC1, SC2 being slanted with respect to each other and the drive axis 388AX. Each of the first and second slanted coupling portions SC1, SC2 join the first and second substrate tines 350, 351 to each other and the end effector drive section 399DE. As an example, the slanted coupling SC joins each of the first and second substrate support tines 350, 351 to each other (see FIGS. 4A-5B) substantially rigidly and unarticulated from one of the slanted coupling portions SC1 to another of the slanted coupling portions SC2. Each axis of motion SAX of the slanted coupling SC (e.g., each axis of motion of each slanted coupling portion SC1, SC2 defined by a respective pitched linear guide 340G, 341G) is slanted with respect to each other axis of motion (e.g., axis 310LAX) of each other coupling (e.g., the coupling formed between the respective carriage 340, 341 and the at least one tine bearing 310) joining the first and second substrate support tines 350, 351 to the base portion 301.

As will be described herein, the pitched linear guides 340G, 341G are pitched at another pitch angle θ3 with respect to at least one linear guide 310 guiding motion of the first and second substrate support tines 350, 351 relative to the base portion 301. The pitch angle θ1, θ2, of the pitched linear guides 340G, 341G relative to the drive axis 388AX, and the other pitch angle θ3, of the pitched linear guides 340G, 341G relative to the at least one linear guide 310 guiding the first and second substrate support tines 350, 351, determine the substantially orthogonal translation from the drive input (from the actuator 390) to the output imparted to the first and second substrate support tines 350, 351. For example, each axis of motion SAX of the slanted coupling SC is arranged at a pitch θ3 (e.g., about 60° but in other aspects more or less than about) 60° with respect to axis of motion (e.g., along axis 310LAX) of each other coupling (e.g., the coupling formed between the respective carriage 340, 341 and the at least one tine bearing 310) joining the first and second substrate support tines 350, 351 to the base portion 301 so as to translate drive input (e.g., from the end effector drive section 399DE as described herein), along the drive axis 388AX of the end effector drive section 399DE, to a drive output imparted to and moving the first and second substrate support tines 350, 351 along an output axis (e.g., along axis 310LAX) substantially orthogonal to the drive input (e.g., input along axis 388AX). The drive output has the output axis (e.g., along axis 310LAX) that is substantially coincident with the each other axis of motion (e.g., axis 310LAX) of each other coupling (e.g., the coupling formed between the respective carriage 340, 341 and the at least one tine bearing 310) joining the first and second substrate support tines 350, 351 to the base portion 301.

The slanted coupling SC is a linear sliding coupling as described herein. For example, each respective slanted coupling portion SC1, SC2 of the slanted coupling SC is formed by and between a respective actuation guide bearing 340G, 341G and a tie member 330C as described herein. Each frame 340F, 341F includes an actuation guide bearing 340G, 341G coupled thereto in any suitable manner (such as with any suitable mechanical or chemical fasteners, etc.). The actuation guide bearings 340G, 341G are arranged on the respective carriages 340, 341 so that each actuation guide bearing 340G, 341G has a pitch θ3 (e.g., about 60° but in other aspects more or less than about) 60° with respect to axis of motion (e.g., along axis 310LAX) of the carriages 340, 341.

The actuation guide bearings 340G, 341G oppose one another to form any suitable inclusive angle θ that has a vertex (see FIGS. 4A and 4B that points towards the wrist axis of the substrate transport arm, see also FIG. 3) disposed so as to be substantially equidistant from each of the first and second substrate support tines 350, 351 (e.g., at least with both the first and second substrate support tines 350, 351 in a closed position), and a line (that is substantially parallel with the longitudinal axis and substantially equidistant from each tine 350, 351—in FIGS. 4A and 4B the line is coincident with the longitudinal axis LAX but may be offset therefrom) bisects the inclusive angle θ (see FIG. 4A). For exemplary purposes only, the inclusive angle θ may be about 60° (where each side θ1, θ2 of the inclusive angle is about) 30°, while in other aspects, the inclusive angle may be more or less than about 60° and each side of the inclusive angle may correspondingly be more or less than about 30°. It is noted that the pitch angle θ1, θ2 may be increased or decreased to vary the constant velocity movement and gripping force TGF (e.g., shallower pitch angles θ1, θ2 may provide a lower constant velocity movement and higher gripping force TGF while wider pitch angles θ1, θ2 may provide a higher constant velocity movement and lower gripping force TGF).

The actuation guide bearings 340G, 341G interface with the tie member 330C. The tie member 330C is coupled to the drive shaft 330 so as to move as a unit with the drive shaft 330 in direction 388. Here, the tie member 330C and the drive shaft 330 form a piston 330P that is common to both actuation guide bearings 340G, 341G. The drive carriage 330C of the piston 330P interfaces with and forms with each actuation guide bearing 340G, 341G a linear slide, a ball slide, a crossed roller slide, a dovetail way slide, a hardened way slide, a linear ball bearing slide, a linear needle roller slide, a sleeve bushing slide, or any other suitable slide. As the tie member 330C is moved in direction 388A (see FIG. 4A), the interaction between the tie member 330C and each of the actuation guide bearings 340G, 341G effects movement of the tines 350, 351 towards each other in direction 389. As the tie member 330C is moved in direction 388B (see FIG. 4B), the interaction between the tie member 330C and each of the actuation guide bearings 340G, 341G effects movement of the tines 350, 351 away from each other in direction 389. Here, the single piston 330P (common to both actuation guide bearings 340G, 341G) effects a dual linear action that transforms action (e.g., linear movement) of the piston 330P into substantially orthogonal dual actions (e.g., linear movement) of each carriage 340, 341 along the at least one tine guide bearing 310.

Referring to FIGS. 4A and 4C, the tie member 330C is biased in direction 388A by any suitable resilient member 370. The resilient member 370 is configured to resist compression of the resilient member 370 and may be any suitable resilient member including, but not limited, to a compression spring, torsion spring, and leaf spring. The resilient member 370 is illustrated, for exemplary purposes only, in the figures as a compression spring captured by the drive shaft 330 (e.g., the drive shaft passes through the compression spring) and butted up against (e.g., interfaced or coupled with) respective interface surface 330S at the end 330E of the tie member 330C and the interface surface 320S of the guide block 320 so as to bias the tie member in direction 388A; however, in other aspects, the resilient member 370 may have any suitable spatial relationship with the tie member 330C and/or guide block 320 to bias the tie member 330C in direction 388A. Biasing of the tie member 330C in direction 388A in turn effects biasing movement of the tines 350, 351 towards each other in direction 389 (see FIG. 4A where the tines 350, 351 are biased in a closed position)). Here, also referring to FIG. 4C, with the end effector 300 holding a substrate S, the tines 350, 351 are biased in movement towards each other (e.g., in the closed position) so as to maintain a persistent substrate gripping force TGF (see FIG. 4C) on the substrate S held on the end effector 300 in the event of a loss of power (e.g., a loss of pneumatic pressure, a loss of hydraulic pressure, or a loss of electricity) to the actuator 390. Maintaining the persistent substrate gripping force TGF may substantially prevent unintentional release (e.g., dropping or otherwise mishandling) of substrates S from the end effector 300 in the event of a loss of power to the actuator 390.

Referring to FIGS. 4B and 4D, the actuator 390 is employed to move the tines 350, 351 from the closed position to an open position (e.g., to increase the distance between the tines from distance D1, corresponding to the closed position-see FIG. 4A, and distance D2, corresponding to the open position). In the example illustrated in FIGS. 4A-4D, actuation of the actuator 390, with the power source 391, drives the drive shaft 330 (and the tie member 330C coupled thereto) in direction 388B against the biasing force BF of the resilient member 370. Movement of the tie member 330C in direction 388B moves the tie member 330C towards the vertex of the inclusive angle θ formed by the actuation guide bearings 340G, 341G so that the tie member 330C spreads or pushes the carriages 340, 341 away from each other. The tie member 330C is a substantially rigid member such that movement of the tie member 330C towards the vertex, of the inclusive angle formed by the actuation guide bearings 340G, 341G, and the sliding interaction between the tie member 330C and each of the actuation guide bearings 340G, 341G drives the carriages 340, 341 (and the tines 350, 351 coupled thereto) away from each other in direction 389 to move the tines 350, 351 to the open position.

As may be realized, de-actuation of the actuator or powering the actuator so as to move the tie member 330C in direction 388A (unopposed to and in the same direction as the biasing force BF of the resilient member 370) effects movement of the tines 350, 351 towards each other to the closed position. For example, movement of the tie member 330C in direction 388A (e.g., under impetus of the resilient member 370 alone or in combination with the actuator 390) away from the vertex, of the inclusive angle formed by the actuation guide bearings 340G, 341G, and the sliding interaction between the tie member 330C and each of the actuation guide bearings 340G, 341G drives or pulls the carriages 340, 341 (and the tines 350, 351 coupled thereto) towards from each other in direction 389 to move the tines 350, 351 to the closed position.

In accordance with the disclosed embodiment, FIG. 4D illustrates the tines 350, 351 of the end effector 300 in an open position where the substrate contacts P1-P4 are arranged to receive or release the substrate S (depending on whether the substrate transport apparatus 300 is picking or placing the substrate S) held by the end effector 300. FIG. 4C illustrates the tines 350, 351 of the end effector 300 in a closed position actively gripping (with the substrate contacts P1-P4 in contact with) the substrate held by the end effector 300. As described herein, the persistent substrate gripping force TGF is applied by the resilient member 370 alone or in combination with the actuator 390 and persists until the tie member 330C is moved towards the vertex of the inclusive angle θ to overcome the biasing force of the resilient member 370 (e.g., such as by the actuator 390 such a when there is power to the actuator or manually such as when there is no power to the actuator).

While the opening of the tines is described, with respect to FIGS. 4A-4D, with movement of the piston 330P in direction 388B, in other aspects movement of the piston 339P in direction 388A may effect opening of the tines. For example, referring to FIGS. 5A and 5B, end effector 300′ is substantially similar to end effector 300; however, in this aspect the vertex of the inclusive angle θ formed by the actuation guide bearings 340G, 341G points towards the cantilevered tips of the tines 350, 351 (see FIGS. 5A and 5B), rather than towards the wrist axis of the substrate transport arm 399 as illustrated in FIGS. 4A-4D (See also FIG. 3). Here, the resilient member 370 is configured to resist extension of the resilient member 370 and may be any suitable resilient member including, but not limited to an extension spring, torsion spring, and leaf spring. The resilient member 370 is illustrated, for exemplary purposes only, in the figures as an extension spring captured by the drive shaft 330 (e.g., the drive shaft 330 passes through the extension spring) and coupled to respective interface surfaces 330S, 320S of the tie member 330C and the guide block 320 so as to bias (via biasing force BF) the tie member 330C in direction 388B; however, in other aspects, the resilient member 370 may have any suitable spatial relationship with the tie member 330C and/or guide block 320 to bias the tie member 330C in direction 388B. Biasing of the tie member 330C in direction 388B in turn effects biasing movement of the tines 350, 351 towards each other in direction 389 (see FIG. 4A) so as to effect the persistent substrate gripping force TGF (see FIG. 4C).

In the example illustrated in FIGS. 5A and 5B, the actuator 390 is employed to move the tines 350, 351 from the closed position (FIG. 5A) to an open position (FIG. 5B; e.g., to increase the distance between the tines from distance D1, corresponding to the closed position, and distance D2, corresponding to the open position). Actuation of the actuator 390, with the power source 391, drives the drive shaft 330 (and the tie member 330C coupled thereto) in direction 388A against the biasing force BF of the resilient member 370. Movement of the tie member 330C in direction 388A moves the tie member 330C towards the vertex of the inclusive angle θ formed by the actuation guide bearings 340G, 341G. Movement of the tie member 330C towards the vertex, of the inclusive angle formed by the actuation guide bearings 340G, 341G, and the sliding interaction between the tie member 330C and each of the actuation guide bearings 340G, 341G drives the carriages 340, 341 (and the tines 350, 351 coupled thereto) away from each other in direction 389 to move the tines 350, 351 to the open position (FIG. 5B) in a manner similar to that described above.

As may be realized, de-actuation of the actuator or powering the actuator so as to move in direction 388B (FIG. 5A) (unopposed to and in the same direction as the biasing force BF of the resilient member 370) effects movement of the tines 350, 351 towards each other to the closed position. For example, movement of the tie member 330C in direction 388B (e.g., under impetus of the resilient member 370 alone or in combination with the actuator 390) away from the vertex, of the inclusive angle formed by the actuation guide bearings 340G, 341G, and the sliding interaction between the tie member 330C and each of the actuation guide bearings 340G, 341G drives the carriages 340, 341 (and the tines 350, 351 coupled thereto) towards from each other in direction 389 to move the tines 350, 351 to the closed position (FIG. 5A) in a manner similar to that described above.

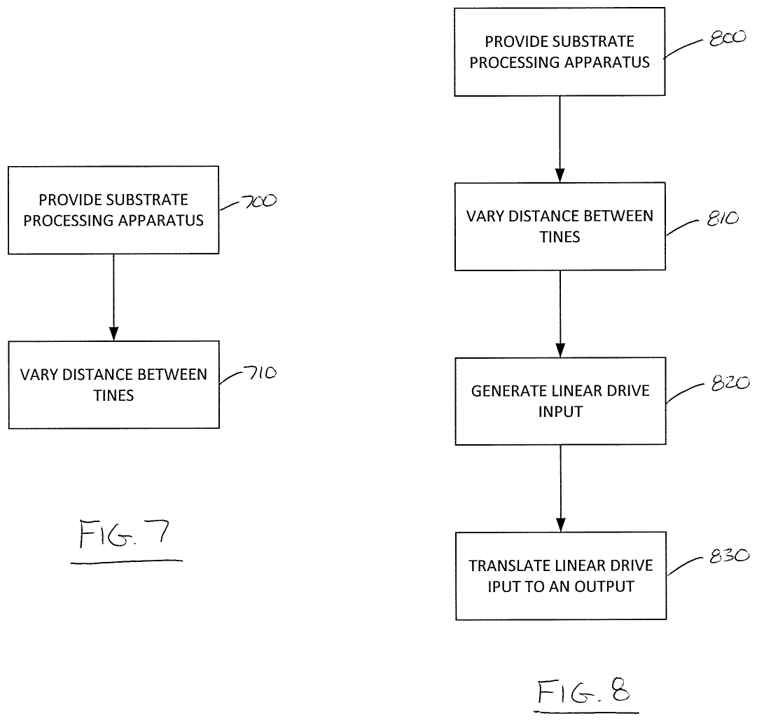

Referring to FIGS. 3-6 and 7, an exemplary method for handing substrates will be described. In accordance with the method a substrate processing apparatus (such as those described above with respect to FIGS. 1A-1H) is provided (FIG. 7, Block 700), where the substrate processing apparatus includes a frame STAF and at least one substrate transport arm 399A connected to the frame STAF. As described herein, the at least one substrate transport arm 399A has at least one end effector 300, 300′, 300″, where each end effector 300, 300′, 300″ has a base portion 301 configured for coupling with a respective substrate transport arm 399A, and a first and second substrate support tines 350, 351 mounted to and dependent from the base portion 301 where at least one of the first and second substrate support tines 350, 351 is movable relative to the base portion 301. A distance between the first and second substrate support tines 350, 351 is varied (FIG. 7, Block 710) by an end effector drive section 399DE. In one or more aspects, each of the first and second substrate support tines 350, 351 are joined, by a slanted coupling SC, to each other substantially rigidly and unarticulated from one of the slanted coupling portions SC1 to another of the slanted coupling portions SC2, where the slanted coupling has a slanted axis of motion SAX where each axis of motion SAX of the slanted coupling SC is slanted with respect to each drive axis 388AX (e.g., the drive axis defined by direction 388) of the end effector drive section 399DE. In other aspects, at least one of the first and second substrate support tines 350, 351 is joined to a rigid and unarticulated slanted coupling SC, where the slanted coupling has a slanted axis of motion SAX where each axis of motion SAX of the slanted coupling SC is slanted with respect to each drive axis 388AX (e.g., the drive axis defined by direction 388) of the end effector drive section 399DE.

Referring to FIGS. 3-6 and 8, an exemplary method for handing substrates will be described. In accordance with the method a substrate processing apparatus (such as those described above with respect to FIGS. 1A-1H) is provided (FIG. 8, Block 800), where the substrate processing apparatus includes a frame STAF and at least one substrate transport arm 399A connected to the frame STAF. As described herein, the at least one substrate transport arm 399A has at least one end effector 300, 300′, 300″, where each end effector 300, 300′, 300″ has a base portion 301 configured for coupling with a respective substrate transport arm 399A and a grip portion 355 with first and second substrate support tines 350, 351 mounted to and dependent from the base portion 301 where at least one of the first and second substrate support tines 350, 351 is movable relative to the base portion 301. A distance between the first and second substrate support tines 350, 351 is varied (FIG. 8, Block 810) with an end effector drive section 399DE. A linear drive input along a drive axis is generated (FIG. 8, Block 820) with an actuator 390 of the end effector, where the actuator 390 is coupled to the grip portion 355 by the slanted coupling SC that operably joint at least one or each of the first and second substrate support tines 350, 351 to the actuator 399DE. The linear drive input of the actuator 399DE is translated, with the slanted coupling SC, to an output (FIG. 8, Block 830) imparting to and moving the at least one or each of the first and second substrate support tines 350, 351 in a direction 389 substantially orthogonal to the linear drive input along the drive axis 388AX.

In accordance with one or more aspects of the disclosed embodiment a substrate processing apparatus includes: a frame; and at least one substrate transport arm connected to the frame, the at least one substrate transport arm having at least one end effector, each end effector having: a base portion configured for coupling with a respective substrate transport arm, a first and second substrate support tines mounted to and dependent from the base portion where at least one of the first and second substrate support tines is movable relative to the base portion, an end effector drive section configured to vary a distance between the first and second substrate support tines, and a slanted coupling that joins each of the first and second substrate support tines to each other substantially rigidly and unarticulated from one of the slanted coupling to another of the slanted coupling, the slanted coupling has a slanted axis of motion wherein each axis of motion of the slanted coupling is slanted with respect to each drive axis of the end effector drive section.

In accordance with one or more aspects of the disclosed embodiment each axis of motion of the slanted coupling is slanted with respect to each other axis of motion of each other coupling joining the first and second substrate support tines to the base portion.

In accordance with one or more aspects of the disclosed embodiment each axis of motion of the slanted coupling is arranged at a pitch with respect to each other axis of motion of each other coupling joining the first and second substrate tines to the base portion so as to translate drive input, along the drive axis of the drive section, to a drive output imparted to and moving the first and second tines along an output axis substantially orthogonal to the drive input.

In accordance with one or more aspects of the disclosed embodiment the output axis is substantially coincident with the each other axis of motion of each other coupling joining the first and second substrate tines to the base portion.

In accordance with one or more aspects of the disclosed embodiment the first and second substrate support tines are moved along the output axis from a release position releasing the substrate and a support position in which the first and second substrate support tines are disposed to contact and support the substrate.

In accordance with one or more aspects of the disclosed embodiment the slanted coupling includes a first and second slanted couplings, each slanted with respect to each other, and joining the first and second substrate tines to each other and the end effector drive section.

In accordance with one or more aspects of the disclosed embodiment the slanted coupling is a linear sliding coupling.

In accordance with one or more aspects of the disclosed embodiment each other coupling joining the first and second substrate tines to the base portion is a linear sliding coupling.

In accordance with one or more aspects of the disclosed embodiment each of the first and second substrate support tines have respective substrate contacts configured to contact and support a substrate held by the end effector between the respective substrate contacts of the first and second substrate support tines.

In accordance with one or more aspects of the disclosed embodiment a substrate processing apparatus includes: a frame; and at least one substrate transport arm connected to the frame, the at least one substrate transport arm having at least one end effector, each end effector having: a base portion configured for coupling with a respective substrate transport arm, a grip portion with first and second substrate support tines mounted to and dependent from the base portion where at least one of the first and second substrate support tines is movable relative to the base portion, an end effector drive section configured to vary a distance between the first and second substrate support tines, and the end effector drive section has an actuator that generates a linear drive input along a drive axis, and the actuator is coupled to the grip portion by a coupling that operably joins each of the first and second substrate support tines to the actuator, wherein the coupling is configured so as to translate the linear drive input, of the actuator, to an output imparted to and moving each of the first and second substrate support tines in a direction substantially orthogonal to the linear drive input along the drive axis.

In accordance with one or more aspects of the disclosed embodiment the coupling has a tie member, rigid and unarticulated, that connects the first and second substrate support tines to each other and to the actuator, so that the drive input is common to the output imparted to and moving each of the first and second substrate support tines.

In accordance with one or more aspects of the disclosed embodiment the tie member has an end joined to the actuator so that the drive input impinges against the tie member, and the tie member spans between and is movably connected to the first and second substrate support tines.

In accordance with one or more aspects of the disclosed embodiment the tie member is restrained by pitched linear guides, pitched at a pitch angle with respect to the drive axis and with respect to each other.

In accordance with one or more aspects of the disclosed embodiment the pitched linear guides are pitched at another pitch angle with respect to at least one linear guide guiding motion of the first and second substrate support tines relative to the base portion.

In accordance with one or more aspects of the disclosed embodiment the pitch angle, of the pitched linear guides relative to the drive axis, and the other pitch angle, of the pitched linear guides relative to the at least one linear guide guiding the first and second substrate support tines, determine the substantially orthogonal translation from the drive input to the output imparted to the first and second substrate support tines.

In accordance with one or more aspects of the disclosed embodiment the first and second substrate support tines are moved along the at least one linear guide, guiding motion of the first and second substrate support tines relative to the base portion, from a release position releasing the substrate and a support position in which the first and second substrate support tines are disposed to contact and support the substrate

In accordance with one or more aspects of the disclosed embodiment the tie member and the pitched linear guides form a slanted coupling that includes a first and second slanted couplings, each slanted with respect to each other, and joining the first and second substrate tines to each other and the end effector drive section.

In accordance with one or more aspects of the disclosed embodiment the slanted coupling is a linear sliding coupling.

In accordance with one or more aspects of the disclosed embodiment each other coupling joining the first and second substrate tines to the base portion is a linear sliding coupling.

In accordance with one or more aspects of the disclosed embodiment each of the first and second substrate support tines have respective substrate contacts configured to contact and support a substrate held by the end effector between the respective substrate contacts of the first and second substrate support tines.

In accordance with one or more aspects of the disclosed embodiment a method for handling substrates is provided. The method includes: providing a substrate processing apparatus having: a frame, at least one substrate transport arm connected to the frame, the at least one substrate transport arm having at least one end effector, where each end effector has a base portion configured for coupling with a respective substrate transport arm, and a first and second substrate support tines mounted to and dependent from the base portion where at least one of the first and second substrate support tines is movable relative to the base portion; and varying, with an end effector drive section, a distance between the first and second substrate support tines; wherein each of the first and second substrate support tines are joined, by a slanted coupling, to each other substantially rigidly and unarticulated from one of the slanted coupling to another of the slanted coupling, the slanted coupling having a slanted axis of motion where each axis of motion of the slanted coupling is slanted with respect to each drive axis of the end effector drive section.

In accordance with one or more aspects of the disclosed embodiment each axis of motion of the slanted coupling is slanted with respect to each other axis of motion of each other coupling joining the first and second substrate support tines to the base portion.

In accordance with one or more aspects of the disclosed embodiment the method further includes imparting to and moving, with a drive output, the first and second tines along an output axis substantially orthogonal to a drive input, wherein each axis of motion of the slanted coupling is arranged at a pitch with respect to each other axis of motion of each other coupling joining the first and second substrate tines to the base portion so as to translate the drive input, along the drive axis of the drive section, to the drive output.

In accordance with one or more aspects of the disclosed embodiment the output axis is substantially coincident with the each other axis of motion of each other coupling joining the first and second substrate tines to the base portion.

In accordance with one or more aspects of the disclosed embodiment the method further includes, moving the first and second substrate support tines along the output axis from a release position releasing the substrate and a support position in which the first and second substrate support tines are disposed to contact and support the substrate.

In accordance with one or more aspects of the disclosed embodiment the slanted coupling includes a first and second slanted couplings, each slanted with respect to each other, and joining the first and second substrate tines to each other and the end effector drive section.

In accordance with one or more aspects of the disclosed embodiment the slanted coupling is a linear sliding coupling.

In accordance with one or more aspects of the disclosed embodiment each other coupling joining the first and second substrate tines to the base portion is a linear sliding coupling.

In accordance with one or more aspects of the disclosed embodiment the method further includes contacting and supporting a substrate, with respective substrate contacts of each of the first and second substrate support tines, held by the end effector between the respective substrate contacts of the first and second substrate support tines.

In accordance with one or more aspects of the disclosed embodiment a method for handling substrates is provided. The method includes: providing a substrate processing apparatus having: a frame, and at least one substrate transport arm connected to the frame, the at least one substrate transport arm having at least one end effector, where each end effector has a base portion configured for coupling with a respective substrate transport arm and a grip portion with first and second substrate support tines mounted to and dependent from the base portion where at least one of the first and second substrate support tines is movable relative to the base portion; varying, with an end effector drive section, a distance between the first and second substrate support tines; generating, with an actuator of the end effector drive section, a linear drive input along a drive axis, where the actuator is coupled to the grip portion by a coupling that operably joins each of the first and second substrate support tines to the actuator; and translating the linear drive input of the actuator, with the coupling, to an output imparted to and moving each of the first and second substrate support tines in a direction substantially orthogonal to the linear drive input along the drive axis.

In accordance with one or more aspects of the disclosed embodiment the coupling has a tie member, rigid and unarticulated, that connects the first and second substrate support tines to each other and to the actuator, so that the drive input is common to the output imparted to and moving each of the first and second substrate support tines.

In accordance with one or more aspects of the disclosed embodiment the tie member has an end joined to the actuator so that the drive input impinges against the tie member, and the tie member spans between and is movably connected to the first and second substrate support tines.

In accordance with one or more aspects of the disclosed embodiment the tie member is restrained by pitched linear guides, pitched at a pitch angle with respect to the drive axis and with respect to each other.

In accordance with one or more aspects of the disclosed embodiment the pitched linear guides are pitched at another pitch angle with respect to at least one linear guide guiding motion of the first and second substrate support tines relative to the base portion.

In accordance with one or more aspects of the disclosed embodiment the pitch angle, of the pitched linear guides relative to the drive axis, and the other pitch angle, of the pitched linear guides relative to the at least one linear guide guiding the first and second substrate support tines, determine the substantially orthogonal translation from the drive input to the output imparted to the first and second substrate support tines.

In accordance with one or more aspects of the disclosed embodiment the method further including moving the first and second substrate support tines along the at least one linear guide, guiding motion of the first and second substrate support tines relative to the base portion, from a release position releasing the substrate and a support position in which the first and second substrate support tines are disposed to contact and support the substrate

In accordance with one or more aspects of the disclosed embodiment the tie member and the pitched linear guides form a slanted coupling that includes a first and second slanted couplings, each slanted with respect to each other, and joining the first and second substrate tines to each other and the end effector drive section.

In accordance with one or more aspects of the disclosed embodiment the slanted coupling is a linear sliding coupling.

In accordance with one or more aspects of the disclosed embodiment each other coupling joining the first and second substrate tines to the base portion is a linear sliding coupling.

In accordance with one or more aspects of the disclosed embodiment the method further including contacting and supporting a substrate, with respective substrate contacts of each of the first and second substrate support tines, held by the end effector between the respective substrate contacts of the first and second substrate support tines.

It should be understood that the foregoing description is only illustrative of the aspects of the disclosed embodiment. Various alternatives and modifications can be devised by those skilled in the art without departing from the aspects of the disclosed embodiment. Accordingly, the aspects of the disclosed embodiment are intended to embrace all such alternatives, modifications and variances that fall within the scope of the appended claims. Further, the mere fact that different features are recited in mutually different dependent or independent claims does not indicate that a combination of these features cannot be advantageously used, such a combination remaining within the scope of the aspects of the invention.

1. A substrate processing apparatus comprising:
a frame; and
at least one substrate transport arm connected to the frame, the at least one substrate transport arm having at least one end effector, each end effector having:
a base portion configured for coupling with a respective substrate transport arm,
a first and second substrate support tines mounted to and dependent from the base portion where at least one of the first and second substrate support tines is movable relative to the base portion,
an end effector drive section configured to vary a distance between the first and second substrate support tines, and
a slanted coupling that joins each of the first and second substrate tines support to each other substantially rigidly and unarticulated from one of the slanted coupling to another of the slanted coupling, the slanted coupling has a slanted axis of motion wherein each axis of motion of the slanted coupling is slanted with respect to each drive axis of the end effector drive section.

2. The substrate processing apparatus of claim 1, wherein each axis of motion of the slanted coupling is slanted with respect to each other axis of motion of each other coupling joining the first and second substrate support tines to the base portion.

3. The substrate processing apparatus of claim 1, wherein each axis of motion of the slanted coupling is arranged at a pitch with respect to each other axis of motion of each other coupling joining the first and second substrate tines to the base portion so as to translate drive input, along the drive axis of the drive section, to a drive output imparted to and moving the first and second tines along an output axis substantially orthogonal to the drive input.

4. The substrate processing apparatus of claim 3, wherein the output axis is substantially coincident with the each other axis of motion of each other coupling joining the first and second substrate tines to the base portion.

5. The substrate processing apparatus of claim 3, wherein the first and second substrate support tines are moved along the output axis from a release position releasing the substrate and a support position in which the first and second substrate support tines are disposed to contact and support the substrate.

6. The substrate processing apparatus of claim 1, wherein the slanted coupling includes a first and second slanted couplings, each slanted with respect to each other, and joining the first and second substrate tines to each other and the end effector drive section.

7. The substrate processing apparatus of claim 1, wherein the slanted coupling is a linear sliding coupling.

8. The substrate processing apparatus of claim 1, wherein each other coupling joining the first and second substrate tines to the base portion is a linear sliding coupling.

9. The substrate processing apparatus of claim 1, each of the first and second substrate support tines have respective substrate contacts configured to contact and support a substrate held by the end effector between the respective substrate contacts of the first and second substrate support tines.

10. A substrate processing apparatus comprising:
a frame; and
at least one substrate transport arm connected to the frame, the at least one substrate transport arm having at least one end effector, each end effector having:
a base portion configured for coupling with a respective substrate transport arm,
a grip portion with first and second substrate support tines mounted to and dependent from the base portion where at least one of the first and second substrate support tines is movable relative to the base portion,
an end effector drive section configured to vary a distance between the first and second substrate support tines, and
the end effector drive section has an actuator that generates a linear drive input along a drive axis, and the actuator is coupled to the grip portion by a coupling that operably joins each of the first and second substrate support tines to the actuator,
wherein the coupling is configured so as to translate the linear drive input, of the actuator, to an output imparted to and moving each of the first and second substrate support tines in a direction substantially orthogonal to the linear drive input along the drive axis.

11. The substrate processing apparatus of claim 10, wherein the coupling has a tie member, rigid and unarticulated, that connects the first and second substrate support tines to each other and to the actuator, so that the drive input is common to the output imparted to and moving each of the first and second substrate support tines.

12. The substrate processing apparatus of claim 10, wherein the tie member has an end joined to the actuator so that the drive input impinges against the tie member, and the tie member spans between and is movably connected to the first and second substrate support tines.

13. The substrate processing apparatus of claim 10, wherein the tie member is restrained by pitched linear guides, pitched at a pitch angle with respect to the drive axis and with respect to each other.

14. The substrate processing apparatus of claim 13, wherein the pitched linear guides are pitched at another pitch angle with respect to at least one linear guide guiding motion of the first and second substrate support tines relative to the base portion.

15. The substrate processing apparatus of claim 14, wherein the pitch angle, of the pitched linear guides relative to the drive axis, and the other pitch angle, of the pitched linear guides relative to the at least one linear guide guiding the first and second substrate support tines, determine the substantially orthogonal translation from the drive input to the output imparted to the first and second substrate support tines.

16. The substrate processing apparatus of claim 13, wherein the first and second substrate support tines are moved along the at least one linear guide, guiding motion of the first and second substrate support tines relative to the base portion, from a release position releasing the substrate and a support position in which the first and second substrate support tines are disposed to contact and support the substrate.

17. The substrate processing apparatus of claim 13, wherein the tie member and the pitched linear guides form a slanted coupling that includes a first and second slanted couplings, each slanted with respect to each other, and joining the first and second substrate tines to each other and the end effector drive section.

18. The substrate processing apparatus of claim 13, wherein the slanted coupling is a linear sliding coupling.

19. The substrate processing apparatus of claim 13, wherein each other coupling joining the first and second substrate tines to the base portion is a linear sliding coupling.

20. The substrate processing apparatus of claim 10, each of the first and second substrate support tines have respective substrate contacts configured to contact and support a substrate held by the end effector between the respective substrate contacts of the first and second substrate support tines.

21. A method for handling substrates, the method comprising:
providing a substrate processing apparatus having:
a frame,
at least one substrate transport arm connected to the frame, the at least one substrate transport arm having at least one end effector, where each end effector has a base portion configured for coupling with a respective substrate transport arm, and
a first and second substrate support tines mounted to and dependent from the base portion where at least one of the first and second substrate support tines is movable relative to the base portion; and
varying, with an end effector drive section, a distance between the first and second substrate support tines;
wherein each of the first and second substrate support tines are joined, by a slanted coupling, to each other substantially rigidly and unarticulated from one of the slanted coupling to another of the slanted coupling, the slanted coupling having a slanted axis of motion where each axis of motion of the slanted coupling is slanted with respect to each drive axis of the end effector drive section.

22. The method of claim 21, wherein each axis of motion of the slanted coupling is slanted with respect to each other axis of motion of each other coupling joining the first and second substrate support tines to the base portion.

23. The method of claim 21, further comprising imparting to and moving, with a drive output, the first and second tines along an output axis substantially orthogonal to a drive input, wherein each axis of motion of the slanted coupling is arranged at a pitch with respect to each other axis of motion of each other coupling joining the first and second substrate tines to the base portion so as to translate the drive input, along the drive axis of the drive section, to the drive output.

24. The method of claim 23, wherein the output axis is substantially coincident with the each other axis of motion of each other coupling joining the first and second substrate tines to the base portion.

25. The method of claim 23, further comprising, moving the first and second substrate support tines along the output axis from a release position releasing the substrate and a support position in which the first and second substrate support tines are disposed to contact and support the substrate.

26. The method of claim 21, wherein the slanted coupling includes a first and second slanted couplings, each slanted with respect to each other, and joining the first and second substrate tines to each other and the end effector drive section.

27. The method of claim 21, wherein the slanted coupling is a linear sliding coupling.

28. The method of claim 21, wherein each other coupling joining the first and second substrate tines to the base portion is a linear sliding coupling.

29. The method of claim 21, further comprising contacting and supporting a substrate, with respective substrate contacts of each of the first and second substrate support tines, held by the end effector between the respective substrate contacts of the first and second substrate support tines.

30. A method for handling substrates, the method comprising:
providing a substrate processing apparatus having:
a frame, and
at least one substrate transport arm connected to the frame, the at least one substrate transport arm having at least one end effector, where each end effector has a base portion configured for coupling with a respective substrate transport arm and a grip portion with first and second substrate support tines mounted to and dependent from the base portion where at least one of the first and second substrate support tines is movable relative to the base portion;
varying, with an end effector drive section, a distance between the first and second substrate support tines;
generating, with an actuator of the end effector drive section, a linear drive input along a drive axis, where the actuator is coupled to the grip portion by a coupling that operably joins each of the first and second substrate support tines to the actuator; and
translating the linear drive input of the actuator, with the coupling, to an output imparted to and moving each of the first and second substrate support tines in a direction substantially orthogonal to the linear drive input along the drive axis.

31. The method of claim 30, wherein the coupling has a tie member, rigid and unarticulated, that connects the first and second substrate support tines to each other and to the actuator, so that the drive input is common to the output imparted to and moving each of the first and second substrate support tines.

32. The method of claim 30, wherein the tie member has an end joined to the actuator so that the drive input impinges against the tie member, and the tie member spans between and is movably connected to the first and second substrate support tines.

33. The method of claim 30, wherein the tie member is restrained by pitched linear guides, pitched at a pitch angle with respect to the drive axis and with respect to each other.

34. The method of claim 33, wherein the pitched linear guides are pitched at another pitch angle with respect to at least one linear guide guiding motion of the first and second substrate support tines relative to the base portion.

35. The method of claim 34, wherein the pitch angle, of the pitched linear guides relative to the drive axis, and the other pitch angle, of the pitched linear guides relative to the at least one linear guide guiding the first and second substrate support tines, determine the substantially orthogonal translation from the drive input to the output imparted to the first and second substrate support tines.

36. The method of claim 33, further comprising moving the first and second substrate support tines along the at least one linear guide, guiding motion of the first and second substrate support tines relative to the base portion, from a release position releasing the substrate and a support position in which the first and second substrate support tines are disposed to contact and support the substrate.

37. The method of claim 33, wherein the tie member and the pitched linear guides form a slanted coupling that includes a first and second slanted couplings, each slanted with respect to each other, and joining the first and second substrate tines to each other and the end effector drive section.

38. The method of claim 33, wherein the slanted coupling is a linear sliding coupling.

39. The method of claim 33, wherein each other coupling joining the first and second substrate tines to the base portion is a linear sliding coupling.

40. The method of claim 30, further comprising contacting and supporting a substrate, with respective substrate contacts of each of the first and second substrate support tines, held by the end effector between the respective substrate contacts of the first and second substrate support tines.
